(19) United States
(12) Patent Application Publication
(10) Pub. No.: US 2024/0246122 A1
(43) Pub. Date: Jul. 25, 2024

(54) SUBSTRATE PROCESSING METHOD

(71) Applicant: SCREEN Holdings Co., Ltd., Kyoto (JP)

(72) Inventors: Masaki INABA, Kyoto (JP); Kana TAHARA, Kyoto (JP); Katsuya AKIYAMA, Kyoto (JP)

(21) Appl. No.: 18/689,824

(22) PCT Filed: May 17, 2022
(86) PCT No.: PCT/JP2022/020462

§ 371 Date: Mar. 6, 2024

(30) Foreign Application Priority Data
Sep. 13, 2021 (JP) 2021-148608

(51) Int. Cl. B08B 3/08; H01L 21/02

(52) U.S. Cl. CPC B08B 3/08; H01L 21/02087

(57) ABSTRACT

A substrate processing method for processing a substrate having a first principal surface and a second principal surface at an opposite side to the first principal surface is provided. A polymer film is formed such as to expose a peripheral edge region of the first principal surface and cover an inner side region of the first principal surface positioned further to an inner side than the peripheral edge region and being adjacent to the peripheral edge region (polymer film forming step). After the polymer film forming step, a first cleaning liquid is supplied to the first principal surface such that the polymer film is maintained on the first principal surface (first cleaning liquid supplying step). After the first cleaning liquid supplying step, a removing liquid that dissolves the polymer film more easily than the first cleaning liquid is supplied to the first principal surface (removing liquid supplying step).

### CROSS REFERENCE TO RELATED APPLICATIONS

This application claims the benefit of priority to Japanese Patent Application No. 2021-148608 filed on Sep. 13, 2021 and the entire contents of this application are hereby incorporated herein by reference.

### TECHNICAL FIELD

The present invention relates to a substrate processing method for processing a substrate.

Examples of substrates to be processed include a semiconductor wafer, a substrate for an FPD (flat panel display) such as a liquid crystal display and an organic EL (electroluminescence) display, etc., a substrate for an optical disc, a substrate for a magnetic disc, a substrate for a magneto-optical disc, a substrate for a photomask, a ceramic substrate, a substrate for a solar cell, and the like.

### BACKGROUND ART

Patent Literature 1 indicated below discloses a substrate processing in which, after an unnecessary thin film attached to an upper surface bevel portion of a substrate is removed by a chemical liquid, the chemical liquid and a film residue attached to the bevel portion is washed off by a rinse liquid.

### CITATION LIST

### Patent Literature

Patent Literature 1: Japanese Patent Application Publication No. 2010-267690

### SUMMARY OF INVENTION

### Technical Problem

With the method disclosed in Patent Literature 1, there is a possibility that, when cleaning the upper surface bevel portion of the substrate, the chemical liquid or the rinse liquid that collides with the upper surface bevel portion of the substrate and splashes back becomes attached to a region of the upper surface of the substrate further to an inner side than the bevel portion and the upper surface of the substrate becomes contaminated.

Thus, a preferred embodiment of the present invention provides, in a substrate processing method for processing a substrate having a first principal surface and a second principal surface at an opposite side to the first principal surface, a substrate processing method with which, during cleaning of a peripheral edge region of the first principal surface of the substrate, contamination of an inner side region of the first principal surface further to an inner side than the peripheral edge region can be suppressed.

### Solution to Problem

A preferred embodiment of the present invention provides a substrate processing method for processing a substrate having a first principal surface and a second principal surface at an opposite side to the first principal surface.

The substrate processing method includes a polymer film forming step of forming a polymer film such as to expose a peripheral edge region of the first principal surface and cover an inner side region of the first principal surface positioned further to an inner side than the peripheral edge region and being adjacent to the peripheral edge region, a first cleaning liquid supplying step of supplying, after the polymer film forming step, a first cleaning liquid to the first principal surface such that the polymer film is maintained on the first principal surface, and a removing liquid supplying step of supplying, after the first cleaning liquid supplying step, a removing liquid that dissolves the polymer film more easily than the first cleaning liquid to the first principal surface.

According to the present method, the polymer film is formed on the first principal surface of the substrate such as to expose the peripheral edge region of the first principal surface. The first cleaning liquid is supplied to the peripheral edge region of the first principal surface such that the polymer film is maintained on the first principal surface and thereafter, the removing liquid is supplied to the first principal surface. Therefore, after cleaning the peripheral edge region of the first principal surface with the first cleaning liquid that is comparatively unlikely to dissolve the polymer film and removing particles and other removal objects from the peripheral edge region of the first principal surface, the polymer film can be removed from the first principal surface by the removing liquid that dissolves the polymer film comparatively easily.

Consequently, the peripheral edge region of the first principal surface can be cleaned by the first cleaning liquid while suppressing, by the polymer film, contamination of the inner side region of the first principal surface.

In a preferred embodiment of the present invention, the polymer film forming step includes a covering step of forming the polymer film having a peripheral edge covering portion that covers the peripheral edge region and an inner side covering portion that covers the inner side region and a peripheral edge exposing step of exposing the peripheral edge region by removing the peripheral edge covering portion from the first principal surface.

According to the present method, after forming the polymer film having the peripheral edge covering portion and the inner side covering portion, the peripheral edge region of the first principal surface is exposed by removing the peripheral edge covering portion. That is, after forming the polymer film across a wide range on the first principal surface, the inner side region can be covered selectively by the polymer film by selectively removing an unnecessary portion.

In a preferred embodiment of the present invention, the peripheral edge exposing step includes a photo-exposing step of photo-exposing (more specifically, selectively photo-exposing) the peripheral edge covering portion and a second cleaning liquid discharging step of discharging, after the photo-exposing step, a second cleaning liquid, by which the photo-exposed peripheral edge covering portion is more easily dissolved than the inner side covering portion, from a second cleaning liquid discharging member toward the first principal surface.

According to the present method, the second cleaning liquid is discharged toward the peripheral edge region after the photo-exposing step. The photo-exposed peripheral edge covering portion is more easily dissolved in the second cleaning liquid than the inner side covering portion that is not photo-exposed. The peripheral edge covering portion can thus be removed from the first principal surface while maintaining the inner side covering portion on the inner side region. The peripheral edge covering portion that is removed by the second cleaning liquid is a portion of the polymer film that has been photo-exposed. Since the portion of the polymer film that has been photo-exposed can thus be removed selectively regardless of a degree of spread of the second cleaning liquid, a removal portion can be demarcated with high precision. The peripheral edge covering portion can thus be removed with high precision in comparison to a case of removing the peripheral edge covering portion using a liquid such as a removing liquid, etc.

In a preferred embodiment of the present invention, the second cleaning liquid discharging step includes a step of discharging the second cleaning liquid toward the inner side region from the second cleaning liquid discharging member.

The peripheral edge covering portion of the polymer film can thus be removed from the first principal surface while protecting the inner side covering portion of the polymer film with the second cleaning liquid. Also, the second cleaning liquid discharged toward the inner side region lands on a front surface of the polymer film. The second cleaning liquid that lands on the front surface of the polymer film spreads radially on the polymer film and is expelled out of the substrate through the peripheral edge region while dissolving the peripheral edge covering portion.

Although the second cleaning liquid may be made to land on the peripheral edge covering portion, in this case, the second cleaning liquid is expelled out of the substrate immediately without spreading across an entirety of the peripheral edge region. On the other hand, by making the second cleaning liquid land on the front surface of the polymer film, the radially spreading second cleaning liquid spreads across the peripheral edge region of a wide range and thus the peripheral edge covering portion can be removed quickly.

In a preferred embodiment of the present invention, the peripheral edge exposing step includes a peripheral edge removing liquid supplying of step discharging the removing liquid toward the second principal surface from a removing liquid discharging member that faces the second principal surface and supplying the removing liquid to the peripheral edge region by making it flow along a peripheral edge of the substrate. The removing liquid discharged from the removing liquid discharging member that faces the second principal surface can thus be supplied to the peripheral edge region without it reaching the inner side region of an upper surface of the substrate. The peripheral edge covering portion can thereby be removed selectively.

In a preferred embodiment of the present invention, the peripheral edge exposing step includes an inclined removing liquid discharging step of discharging the removing liquid toward the peripheral edge region obliquely with respect to the first principal surface from an inclined removing liquid discharging member that faces the first principal surface.

According to the present method, the removing liquid is discharged toward the peripheral edge region obliquely with respect to the first principal surface from the inclined removing liquid discharging member. The removing liquid can thus be supplied to the peripheral edge covering portion, covering the peripheral edge region, while suppressing the removing liquid that landed on the peripheral edge region from flowing along the first principal surface toward the inner side region. The removing liquid can thus be supplied directly from the inclined removing liquid discharging member to the peripheral edge region of the first principal surface. The peripheral edge covering portion can be removed with high precision in comparison to a case of supplying the removing liquid from the second principal surface to the peripheral edge region of the first principal surface by making it flow along the peripheral edge of the substrate.

In a preferred embodiment of the present invention, the first cleaning liquid supplying step includes a step of discharging the first cleaning liquid from a first cleaning liquid discharging member toward the inner side region.

The peripheral edge region of the first principal surface can thus be cleaned while protecting a portion of the polymer film on the inner side region of the first principal surface with the first cleaning liquid. Also, the first cleaning liquid discharged toward the inner side region lands on the front surface of the polymer film. The first cleaning liquid that lands on the front surface of the polymer film spreads radially on the polymer film and is expelled out of the substrate through the peripheral edge region of the first principal surface.

Although the first cleaning liquid may be made to land on the peripheral edge region, in this case, the first cleaning liquid is expelled out of the substrate immediately without spreading across the entirety of the peripheral edge region. On the other hand, by making the first cleaning liquid land on the front surface of the polymer film, the radially spreading first cleaning liquid can be made to spread across the peripheral edge region of a wide range and thus efficient cleaning by the first cleaning liquid is made possible.

In a preferred embodiment of the present invention, the substrate processing method further includes a hydrophobizing step of hydrophobizing (more specifically, selectively hydrophobizing) the peripheral edge region before the polymer film forming step. The polymer film forming step includes a polymer-containing liquid supplying step of supplying a polymer-containing liquid containing a polymer and a solvent to the first principal surface of the substrate and an evaporation forming step of evaporating the solvent from the polymer-containing liquid on the first principal surface and forming the polymer film.

According to the present method, the peripheral edge region can be hydrophobized. Attachment of the polymer-containing liquid to the peripheral edge region can thus be suppressed. On the other hand, the polymer-containing liquid is likely to be retained on the inner side region that is not subject to hydrophobization processing. Therefore, if the polymer-containing liquid is supplied to an entirety of the first principal surface, the polymer film that selectively covers the inner side region in a state of exposing the peripheral edge region can be formed without devising a special means for supplying the polymer-containing liquid.

In a preferred embodiment of the present invention, the hydrophobizing step includes a hydrophobizing liquid supplying step of discharging a hydrophobizing liquid toward the second principal surface from a hydrophobizing liquid discharging member and making the hydrophobizing liquid reach the peripheral edge region by making the hydrophobizing liquid flow along the peripheral edge of the substrate. The hydrophobizing liquid discharged from the hydrophobizing liquid discharging member that faces the second principal surface can thus be supplied to the peripheral edge region and the peripheral edge region can be hydrophobized selectively.

The above and yet other objects, features, and effects of the present invention will become more apparent from the following description of the preferred embodiments made with reference to the attached drawings.

### BRIEF DESCRIPTION OF DRAWINGS

FIG. 1 is a plan view for describing an arrangement example of a substrate processing apparatus according to a first preferred embodiment of the present invention.

FIG. 2 is a schematic view for describing an arrangement of a wet processing unit included in the substrate processing apparatus.

FIG. 3 is a schematic view for describing an arrangement of a dry processing unit included in the substrate processing apparatus.

FIG. 4 is a block diagram for describing an electrical arrangement of the substrate processing apparatus.

FIG. 5 is a flowchart for describing an example of substrate processing executed by the substrate processing apparatus.

FIG. 6A is a schematic view for describing a condition of a substrate when the substrate processing is being performed.

FIG. 6B is a schematic view for describing the condition of the substrate when the substrate processing is being performed.

FIG. 6C is a schematic view for describing the condition of the substrate when the substrate processing is being performed.

FIG. 6D is a schematic view for describing the condition of the substrate when the substrate processing is being performed.

FIG. 6E is a schematic view for describing the condition of the substrate when the substrate processing is being performed.

FIG. 6F is a schematic view for describing the condition of the substrate when the substrate processing is being performed.

FIG. 7A is a perspective view of the substrate during the substrate processing.

FIG. 7B is a perspective view of the substrate during the substrate processing.

FIG. 7C is a perspective view of the substrate during the substrate processing.

FIG. 8A is a schematic view for describing changes in a peripheral edge region of an upper surface of the substrate during the substrate processing.

FIG. 8B is a schematic view for describing the changes in the peripheral edge region of the upper surface of the substrate during the substrate processing.

FIG. 8C is a schematic view for describing the changes in the peripheral edge region of the upper surface of the substrate during the substrate processing.

FIG. 9A is a schematic view for describing a first modification example of a peripheral edge covering portion removing step.

FIG. 9B is a schematic view for describing a second modification example of the peripheral edge covering portion removing step.

FIG. 10 is a plan view for describing an arrangement example of a substrate processing apparatus according to a second preferred embodiment of the present invention.

FIG. 11 is a schematic view for describing an arrangement of a first example of a wet processing unit included in the substrate processing apparatus according to the second preferred embodiment.

FIG. 12 is a flowchart for describing a first example of substrate processing executed by the substrate processing apparatus according to the second preferred embodiment.

FIG. 13A is a schematic view for describing a condition of a substrate when the first example of substrate processing according to the second preferred embodiment is being performed.

FIG. 13B is a schematic view for describing the condition of the substrate when the first example of substrate processing according to the second preferred embodiment is being performed.

FIG. 13C is a schematic view for describing the condition of the substrate when the first example of substrate processing according to the second preferred embodiment is being performed.

FIG. 13D is a schematic view for describing the condition of the substrate when the first example of substrate processing according to the second preferred embodiment is being performed.

FIG. 13E is a schematic view for describing the condition of the substrate when the first example of substrate processing according to the second preferred embodiment is being performed.

FIG. 14 is a schematic view for describing an arrangement of a second example of a wet processing unit included in the substrate processing apparatus according to the second preferred embodiment.

FIG. 15 is a schematic view for describing a condition of a substrate when a second example of substrate processing according to the second preferred embodiment is being performed.

FIG. 16 is a schematic view for describing an arrangement of a third example of a wet processing unit included in the substrate processing apparatus according to the second preferred embodiment.

FIG. 17 is a flowchart for describing a third example of substrate processing executed by the substrate processing apparatus according to the second preferred embodiment.

FIG. 18A is a schematic view for describing a condition of a substrate when the third example of substrate processing according to the second preferred embodiment is being performed.

FIG. 18B is a schematic view for describing the condition of the substrate when the third example of substrate processing according to the second preferred embodiment is being performed.

FIG. 18C is a schematic view for describing the condition of the substrate when the third example of substrate processing according to the second preferred embodiment is being performed.

FIG. 19 is a schematic view for describing a modification example of a peripheral edge region cleaning step.

### DESCRIPTION OF EMBODIMENTS

### <Arrangement of a Substrate Processing Apparatus According to a First Preferred Embodiment>

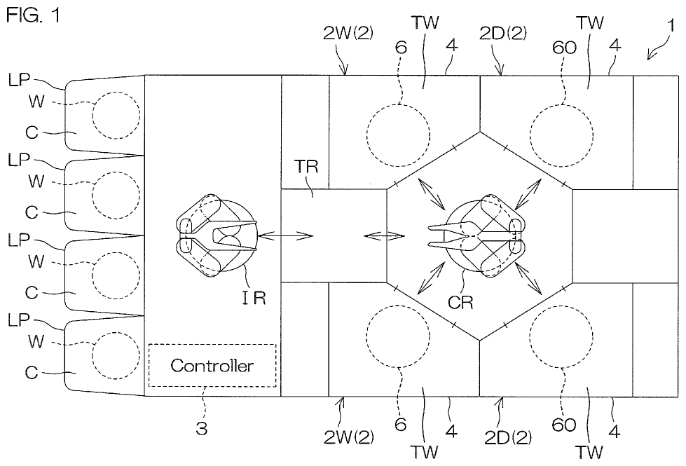

FIG. 1 is a plan view for describing an arrangement example of a substrate processing apparatus 1 according to a first preferred embodiment of the present invention.

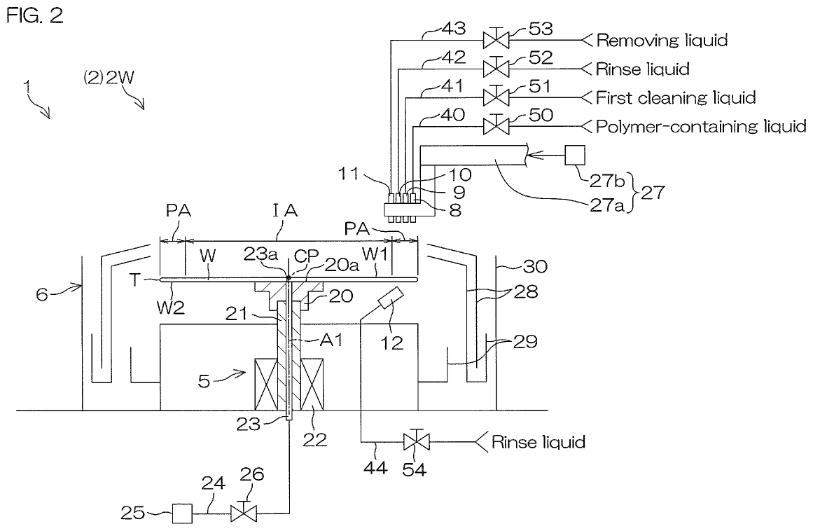

The substrate processing apparatus 1 is a single substrate processing type apparatus that processes substrates W one by one. In the present preferred embodiment, each substrate W has a disk shape. The substrate W is a substrate such as a silicon wafer, etc., and has a pair of principal surfaces. A principal surface may be a device surface on which a device having an uneven pattern is formed or may be a non-device surface on which a device is not formed. The pair of principal surfaces includes a first principal surface W1 (see FIG. 2 to be described below) and a second principal surface W2 (see FIG. 2 to be described below) at an opposite side to the first principal surface W1. In the present preferred embodiment, the first principal surface W1 is a device surface and the second principal surface W2 is a non-device surface.

In the following, unless described in particular otherwise, an example where an upper surface (principal surface at an upper side) is the first principal surface W1 and a lower surface (principal surface at a lower side) is the second principal surface W2 shall be described.

The substrate processing apparatus 1 includes a plurality of processing units 2 for processing substrates W, load ports LP (container holding units) on which are placed carriers C (containers) each housing a plurality of the substrates W to be processed by the processing units 2, transfer robots (first transfer robot IR and second transfer robot CR) that transfer the substrates W between the load ports LP and the processing units 2, and a controller 3 that controls respective members included in the substrate processing apparatus 1.

The first transfer robot IR transfers the substrates W between the carriers C and the second transfer robot CR. The second transfer robot CR transfers the substrates W between the first transfer robot IR and the processing units 2. Each of the transfer robots is, for example, an articulated arm robot.

The plurality of processing units 2 are aligned along a transfer route TR and at both sides of the transfer route TR through which the substrates W are transferred by the second transfer robot CR and are also stacked and aligned in an up/down direction.

The plurality of processing units 2 form four processing towers TW respectively disposed at four positions that are separated horizontally. Each processing tower TW includes a plurality of processing units 2 that are stacked in the up/down direction. Two each of the processing towers TW are disposed at respective sides of the transfer route TR.

The plurality of processing units 2 include a plurality of dry processing units 2D that each process a substrate W with the substrate W being dry as it is and a plurality of wet processing units 2W that each process a substrate W with processing liquids. Although details shall be described later, a polymer-containing liquid, a first cleaning liquid, a rinse liquid, a removing liquid, etc., can be cited as the processing liquids.

Each processing unit 2 includes a chamber 4 that houses a substrate W during substrate processing. The chamber 4 includes an inlet/outlet (not shown) through which the substrate W is carried into the chamber 4 and the substrate W is carried out from the chamber 4 by the second transfer robot CR and a shutter unit (not shown) that opens/closes the inlet/outlet.

Each wet processing unit 2W processes a substrate W inside a processing cup 6 disposed inside the chamber 4. Each dry processing unit 2D processes a substrate W in a state where the substrate W is placed on a stage 60 disposed inside the chamber 4.

### <Arrangement of a Wet Processing Unit According to the First Preferred Embodiment>

FIG. 2 is a schematic view for describing an arrangement of a wet processing unit 2W.

The wet processing unit 2W includes a spin chuck 5 that rotates the substrate W around a rotational axis A1 while holding the substrate W in a predetermined processing orientation, a plurality of upper surface processing liquid nozzles that discharge processing liquids toward the upper surface (first principal surface W1) of the substrate W held by the spin chuck 5, and a lower surface rinse liquid nozzle 12 that discharges the rinse liquid toward the lower surface (second principal surface W2) of the substrate W held by the spin chuck 5. The plurality of upper surface processing liquid nozzles include a polymer-containing liquid nozzle 8, a first cleaning liquid nozzle 9, a rinse liquid nozzle 10, and a removing liquid nozzle 11.

The spin chuck 5, the plurality of upper surface processing liquid nozzles, and the lower surface rinse liquid nozzle 12 are disposed inside the chamber 4.

The rotational axis A1 passes through a center portion CP of the upper surface of the substrate W and is orthogonal to the respective principal surfaces of the substrate W held in the processing orientation. In the present preferred embodiment, the processing orientation is a horizontal orientation in which the principal surfaces of the substrate W are horizontal surfaces. The horizontal orientation is the orientation of the substrate W shown in FIG. 2 and when the processing orientation is the horizontal orientation, the rotational axis A1 extends vertically.

The spin chuck 5 is surrounded by a processing cup 6. The spin chuck 5 includes a spin base 20 that suctions the lower surface of the substrate W and holds the substrate W in the processing orientation, a rotating shaft 21 that extends along the rotational axis A1 and is coupled to the spin base 20, and a rotational driving mechanism 22 that rotates the rotating shaft 21 around the rotational axis A1.

The spin base 20 has a suction surface 20a that suctions the lower surface of the substrate W. The suction surface 20a is, for example, an upper surface of the spin base 20 and is a circular surface through a center portion of which the rotational axis A1 passes. A diameter of the suction surface 20a is smaller than a diameter of the substrate W. An upper end portion of the rotating shaft 21 is coupled to the spin base 20.

A suction path 23 is inserted in the spin base 20 and the rotating shaft 21. The suction path 23 has a suction port 23a that is exposed from a center of the suction surface 20a of the spin base 20. The suction path 23 is linked to a suction piping 24. The suction piping 24 is linked to a vacuum pump or other suction apparatus 25. The suction apparatus 25 may constitute a portion of the substrate processing apparatus 1 or may be a separate apparatus from the substrate processing apparatus 1 that is included in a facility in which the substrate processing apparatus 1 is installed.

A suction valve 26 that opens/closes the suction piping 24 is provided in the suction piping 24. By opening the suction valve 26, the substrate W disposed on the suction surface 20a of the spin base 20 is suctioned to the suction port 23a of the suction path 23. The substrate W is thereby suctioned onto the suction surface 20a from below and held in the processing orientation.

The spin base 20 is rotated by the rotating shaft 21 being rotated by the rotational driving mechanism 22. The substrate W is thereby rotated around the rotational axis A1 together with the spin base 20.

The spin base 20 is an example of a substrate holding member (substrate holder) that holds the substrate W in the predetermined processing orientation (horizontal orientation). The spin chuck 5 is an example of a rotation holding unit that rotates the substrate W around the rotational axis A1 while holding the substrate W in the predetermined processing orientation (horizontal orientation). The spin chuck 5 is also called a suction rotating unit that rotates the substrate W while suctioning the substrate W onto the suction surface 20a.

The plurality of upper surface processing liquid nozzles are moved integrally in a horizontal direction by a first nozzle driving mechanism 27. The first nozzle driving mechanism 27 can move the respective upper surface processing liquid nozzles between a central position and a retreat position.

The central position is a position at which discharge ports of the upper surface processing liquid nozzles face a rotation center (center portion CP) of the upper surface of the substrate W. The retreat position is a position at which the discharge ports of the upper surface processing liquid nozzles do not face the upper surface of the substrate W and is a position at an outer side of the processing cup 6.

The first nozzle driving mechanism 27 can also position the upper surface processing liquid nozzles at a peripheral edge position. The peripheral edge position is a position at which the discharge ports of the upper surface processing liquid nozzles face a peripheral edge region PA of the upper surface of the substrate W.

The peripheral edge region PA is a region of the upper surface of the substrate W that is of annular shape and includes a surrounding portion of a peripheral edge T of the substrate W. A region of circular shape of the upper surface of the substrate W that is positioned further to an inner side than the peripheral edge region PA and is adjacent to the peripheral edge region PA is called an inner side region IA. The inner side region IA is a region that includes the center portion CP of the upper surface of the substrate W and its surrounding region. The peripheral edge region PA is a region in which an uneven pattern is not formed and the inner side region IA is a region in which the uneven pattern is formed.

An inner peripheral end of the peripheral edge region PA is positioned, for example, at a position of not less than 0.2 mm and not more than 3.0 mm from the peripheral edge T of the substrate W. That is, a width of the peripheral edge region PA is not less than 0.2 mm and not more than 3.0 mm.

The peripheral edge region PA of the upper surface of the substrate W is linked via a tip (peripheral edge T) of the substrate W to a peripheral edge region of the lower surface of the substrate W. The peripheral edge region of the lower surface of the substrate W is a region of the lower surface of the substrate W that is of annular shape and includes a surrounding portion of the peripheral edge T of the substrate W. The peripheral edge regions of the upper surface and the lower surface of the substrate W and the peripheral edge T of the substrate W are referred to collectively at times as a bevel portion.

The first nozzle driving mechanism 27 includes an arm 27a that supports the plurality of upper surface processing liquid nozzles and an arm driving mechanism 27b that moves the arm 27a in a direction (horizontal direction) along the upper surface of the substrate W. The arm driving mechanism 27b includes an actuator such as an electric motor, an air cylinder, etc.

The arm driving mechanism 27b may be a pivoting type driving mechanism that pivots the arm 27a around a predetermined pivoting axis or may be a linear driving mechanism that moves the arm 27a rectilinearly in a direction in which the arm 27a extends. The arm driving mechanism 27b may also be arranged such as to be capable of moving the upper surface processing liquid nozzles (more specifically, the arm 27a) in a vertical direction as well.

The plurality of upper surface processing liquid nozzles include the polymer-containing liquid nozzle 8 that discharges a continuous stream of the polymer-containing liquid toward the upper surface of the substrate W held by the spin chuck 5, the first cleaning liquid nozzle 9 that discharges the first cleaning liquid toward the upper surface of the substrate W held by the spin chuck 5, the rinse liquid nozzle 10 that discharges the rinse liquid toward the upper surface of the substrate W held by the spin chuck 5, and the removing liquid nozzle 11 that discharges a continuous stream of the removing liquid toward the upper surface of the substrate W held by the spin chuck 5.

The polymer-containing liquid that is discharged from the polymer-containing liquid nozzle 8 contains a polymer and a solvent.

With the polymer contained in the polymer-containing liquid, a solubility in the first cleaning liquid is lower than a solubility in the removing liquid. With the polymer, a solubility in the rinse liquid is lower than the solubility in the removing liquid. Put in another way, the polymer is more easily dissolved in the removing liquid than in the first cleaning liquid and the rinse liquid. The polymer is, for example, a photoresist of positive type. The polymer does not have to be a photoresist as long as it has a property that the solubility in the rinse liquid is increased by irradiation of light.

The solvent contained in the polymer-containing liquid has a property of dissolving the polymer. The solvent contains, for example, an organic solvent such as isopropanol (IPA), etc.

The solvent contains at least one type among an alcohol such as ethanol (EtOH), IPA, etc., an ethylene glycol monoalkyl ether such as ethylene glycol monomethyl ether, ethylene glycol monoethyl ether, etc., an ethylene glycol monoalkyl ether acetate such as ethylene glycol monomethyl ether acetate, ethylene glycol monoethyl ether acetate, etc., a propylene glycol monoalkyl ether such as propylene glycol monomethyl ether (PGME), propylene glycol monoethyl ether (PGEE), etc., a lactic ester such as methyl lactate, ethyl lactate (EL), etc., an aromatic hydrocarbon such as toluene, xylene, etc., and a ketone such as acetone, methyl ethyl ketone, 2-heptanone, cyclohexanone, etc.

The polymer-containing liquid nozzle 8 is connected to a polymer-containing liquid piping 40 that guides the polymer-containing liquid to the polymer-containing liquid nozzle 8. The polymer-containing liquid piping 40 is provided with a polymer-containing liquid valve 50 that opens/closes the polymer-containing liquid piping 40. When the polymer-containing liquid valve 50 is opened, the polymer-containing liquid of a continuous stream is discharged from the polymer-containing liquid nozzle 8.

That the polymer-containing liquid valve 50 is provided in the polymer-containing liquid piping 40 may mean that the polymer-containing liquid valve 50 is interposed in the polymer-containing liquid piping 40. The same also applies to other valves described below.

Although not illustrated, the polymer-containing liquid valve 50 includes a valve body with a valve seat provided in an interior, a valve element that opens/closes the valve seat, and an actuator that moves the valve element between an open position and a closed position. The other valves also have the same arrangement.

By at least a portion of the solvent evaporating from the polymer-containing liquid supplied to the upper surface of the substrate W, the polymer-containing liquid on the substrate W changes to a polymer film of semisolid state or solid state.

The semisolid state is a state in which a solid component and a liquid component are mixed or a state of having a viscosity of a degree such that a certain shape can be maintained on the substrate W. The solid state is a state in which a liquid component is not contained and is arranged from just a solid component. A polymer film with the solvent remaining is called a semisolid film and a polymer film with which the solvent is eliminated completely is called a solid film. The polymer film thus does not spread on the upper surface of the substrate W and stays at the position at which it is formed.

The first cleaning liquid that is discharged from the first cleaning liquid nozzle 9 is a liquid that cleans the substrate W to remove removal objects from the substrate W. The removal objects are objects that form on the substrate W in a preprocessing performed before processing by the substrate processing apparatus 1. That is, the removal objects are not a part of the substrate W but are attached objects that are attached to the principal surfaces of the substrate W.

The removal objects are, for example, particles such as film residues, etc. The particles are, for example, an insulator or a metal. Specifically, the particles are constituted of silicon nitride (SiN), titanium nitride (TiN), and tungsten (W). The removal objects are mainly attached to a vicinity of the peripheral edge T of the substrate W, specifically, the bevel portion of the substrate W.

In the preprocessing, chuck pins that grip the bevel portion of the substrate W to hold the orientation of the substrate W are used at times. In this case, the bevel portion of the substrate W is contaminated by the chuck pins and particles become attached to the bevel portion of the substrate W. Also, when a film is being removed from the upper surface of the substrate W, a liquid is unlikely to enter locations of the substrate W in contact with the chuck pins and the film is not removed sufficiently from the contact locations of the substrate W and the chuck pins in some cases. Particles form at the bevel portion of the substrate W in such cases as well.

By the particles formed at the bevel portion becoming attached to the uneven pattern in the inner side region IA of the upper surface (first principal surface W1) that is the device surface, a fault such as a defect, etc., may occur.

The first cleaning liquid that is discharged from the first cleaning liquid nozzle 9 is a liquid that removes the removal objects present on the substrate W. The first cleaning liquid preferably has a property of dissolving the removal objects.

The first cleaning liquid contains, for example, hydrogen peroxide water (H₂O₂), hydrofluoric acid (HF), dilute hydrofluoric acid (DHF), buffered hydrofluoric acid (BHF), hydrochloric acid (HCL), HPM liquid (hydrochloric acid-hydrogen peroxide mixture), SPM liquid (sulfuric acid/hydrogen peroxide mixture), ammonia water, TMAH liquid (tetramethylammonium hydroxide solution), or APM liquid (ammonia-hydrogen peroxide mixture).

Hydrofluoric acid, dilute hydrofluoric acid, buffered hydrofluoric acid, hydrochloric acid, HPM liquid, and SPM liquid are classified as acidic cleaning liquids. Ammonia water, APM liquid, and TMAH liquid are classified as alkaline cleaning liquids. If the removal objects are an insulator, it is preferable to use an alkaline cleaning liquid as the first cleaning liquid and if the removal objects are a metal, it is preferable to use an acidic cleaning liquid as the first cleaning liquid.

The first cleaning liquid may be hydrogen peroxide water, hydrofluoric acid, dilute hydrofluoric acid, buffered hydrofluoric acid, hydrochloric acid, HPM liquid, SPM liquid, or a mixed liquid containing at least two types of these. Also, the first cleaning liquid may be ammonia water, APM liquid, TMAH liquid, or a mixed liquid containing at least two types of these.

The first cleaning liquid nozzle 9 is connected to a first cleaning liquid piping 41 that guides the first cleaning liquid to the first cleaning liquid nozzle 9. The first cleaning liquid piping 41 is provided with a first cleaning liquid valve 51 that opens/closes the first cleaning liquid piping 41. When the first cleaning liquid valve 51 is opened, the first cleaning liquid of a continuous stream is discharged from the first cleaning liquid nozzle 9.

The rinse liquid that is discharged from the rinse liquid nozzle 10 is a liquid that rinses the upper surface of the substrate W and removes the first cleaning liquid from the upper surface of the substrate W.

The rinse liquid is, for example, water such as DIW, etc. However, the rinse liquid is not restricted to DIW. The rinse liquid is not restricted to DIW and, for example, may be DIW, carbonated water, electrolyzed ion water, aqueous hydrochloric acid solution of dilute concentration (for example, of not less than 1 ppm and not more than 100 ppm), ammonia water of dilute concentration (for example, of not less than 1 ppm and not more than 100 ppm), or reduced water (hydrogen water).

The rinse liquid nozzle 10 is connected to a rinse liquid piping 42 that guides the rinse liquid to the rinse liquid nozzle 10. The rinse liquid piping 42 is provided with a rinse liquid valve 52 that opens/closes the rinse liquid piping 42. When the rinse liquid valve 52 is opened, a continuous stream of the rinse liquid is discharged from the rinse liquid nozzle 10.

Since the polymer film contains the photoresist of positive type in the present preferred embodiment, a portion of the polymer film that is photo-exposed can be removed from being on the substrate W by the rinse liquid as a second cleaning liquid.

The removing liquid that is discharged from the removing liquid nozzle 11 is a liquid that removes the polymer film from the upper surface of the substrate W by dissolving the polymer film. The removing liquid is a liquid that dissolves the polymer film more easily than the first cleaning liquid and the rinse liquid. The polymer film remaining on the upper surface of the substrate W may be removed from the upper surface of the substrate W by being pushed out of the substrate W by an energy acting from a liquid stream of the removing liquid.

The removing liquid discharged from the removing liquid nozzle 11 is, for example, an organic solvent such as IPA, etc. As the removing liquid, a liquid listed as an organic solvent used as the solvent of the polymer containing liquid can be used. That is, the same type of liquid as the solvent of the polymer-containing liquid can be used as the removing liquid.

The removing liquid nozzle 11 is connected to a removing liquid piping 43 that guides the removing liquid to the removing liquid nozzle 11. The removing liquid piping 43 is provided with a removing liquid valve 53 that opens/closes the removing liquid piping 43. When the removing liquid valve 53 is opened, the removing liquid of a continuous stream is discharged from the removing liquid nozzle 11.

As the rinse liquid discharged from the lower surface rinse liquid nozzle 12, a liquid listed as the rinse liquid discharged from the rinse liquid nozzle 10 can be used.

The lower surface rinse liquid nozzle 12 is connected to a lower surface rinse liquid piping 44 that guides the rinse liquid to the lower surface rinse liquid nozzle 12. The lower surface rinse liquid piping 44 is provided with a lower surface rinse liquid valve 54 that opens/closes the lower surface rinse liquid piping 44.

The lower surface rinse liquid nozzle 12 is fixed in position with respect to the spin chuck 5. The lower surface rinse liquid nozzle 12 has a discharge port directed toward the peripheral edge region of the lower surface of the substrate W. When the lower surface rinse liquid valve 54 is opened, a continuous stream of the rinse liquid is discharged from the lower surface rinse liquid nozzle 12 toward the peripheral edge region of the lower surface. The lower surface rinse liquid nozzle 12 suffices to supply the rinse liquid to the lower surface of the substrate W and does not necessarily have to discharge the rinse liquid toward the peripheral edge region of the lower surface of the substrate W.

An arrangement of the processing cup 6 is not restricted in particular. The processing cup 6 includes, for example, a plurality (two in FIG. 2) of guards 28 that receive a processing liquid splashed outward from the substrate W held by the spin chuck 5, a plurality (two in FIG. 2) of cups 29 that respectively receive the processing liquid guided downward by the plurality of guards 28, and an outer wall member 30 of circular cylindrical shape that surrounds the plurality of guards 28 and the plurality of cups 29.

Each guard 28 has a form of a cylindrical shape that surrounds the spin chuck 5 in plan view. Upper end portions of the respective guards 28 are inclined such as to be directed toward an inner side of the guards 28. Each cup 29 has a form of an annular groove that is opened upward. The plurality of guards 28 and the plurality of cups 29 are disposed on the same axis.

The plurality of guards 28 are elevated and lowered individually by a guard elevating/lowering mechanism (not shown). The guard elevating/lowering mechanism includes, for example, a plurality of actuators that elevatingly/loweringly drive the plurality of guards 28 respectively. The plurality of actuators include at least either of an electric motor and an air cylinder.

### <Arrangement of a Dry Processing Unit>

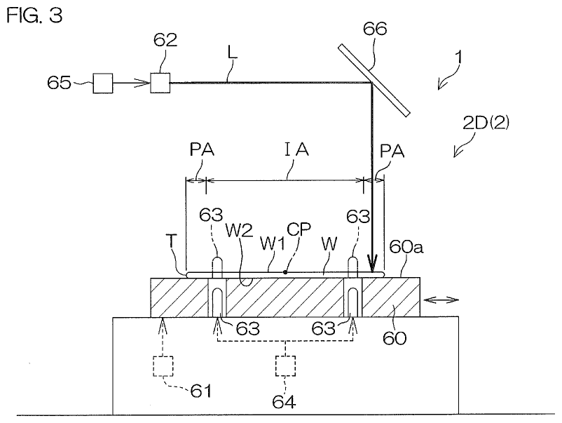

FIG. 3 is a schematic view for describing an arrangement of a dry processing unit 2D included in the substrate processing apparatus 1.

The dry processing unit 2D is a photo-exposing unit that is disposed inside the chamber 4 and photo-exposes the polymer film on the substrate W. The dry processing unit 2D includes a stage driving mechanism 61 that moves the stage 60 in a direction (horizontal direction) along the upper surface of the substrate W, a light emitting member 62 that emits light, a plurality of lift pins 63 that penetrate and move up and down through the stage 60, and a pin driving mechanism 64 that moves the plurality of lift pins 63.

The stage 60 has a mounting surface 60a on which the substrate W is placed. The stage driving mechanism 61 includes, for example, an actuator that drives the stage 60. The actuator includes at least either of an electric motor and an air cylinder.

The light emitting member 62 includes, for example, a light source that emits a light L. The light L emitted from the light emitting member 62 is, for example, of ultraviolet rays of not less than 1 nm and not more than 400 nm. The light source is, for example, a laser light source that emits a laser light. The laser light source is, for example, an excimer lamp that emits an excimer laser.

A power supply or other energizing unit 65 is connected to the light emitting member 62 and by electric power being supplied from the energizing unit 65, the light L is emitted from the light emitting member 62.

The dry processing unit 2D may further include a mirror or other reflecting member 66 that reflects the light L toward the peripheral edge region PA of the upper surface of the substrate W. Although with the present preferred embodiment, just one reflecting member 66 is illustrated, a plurality of the reflecting members 66 that reflect the light L emitted from the light emitting member 62 may be provided instead. An irradiation position of the light L can be changed by changing a reflection angle of the reflecting member 66.

The plurality of lift pins 63 are respectively inserted in a plurality of penetrating holes that penetrate through the stage 60. The plurality of lift pins 63 are moved in an orthogonal direction (vertical direction) with respect to the principal surfaces of the substrate W by the pin driving mechanism 64. The plurality of lift pins 63 move between an upper position (position indicated by alternate long and two short dashed lines in FIG. 3) of supporting the substrate W above the mounting surface 60a and a lower position (position indicated by solid lines in FIG. 3) at which tip portions (upper end portions) sink below the mounting surface 60a.

The pin driving mechanism 64 may be an electric motor or an air cylinder or may be an actuator other than these.

### <Electrical Arrangement of Substrate Processing According to the First Preferred Embodiment>

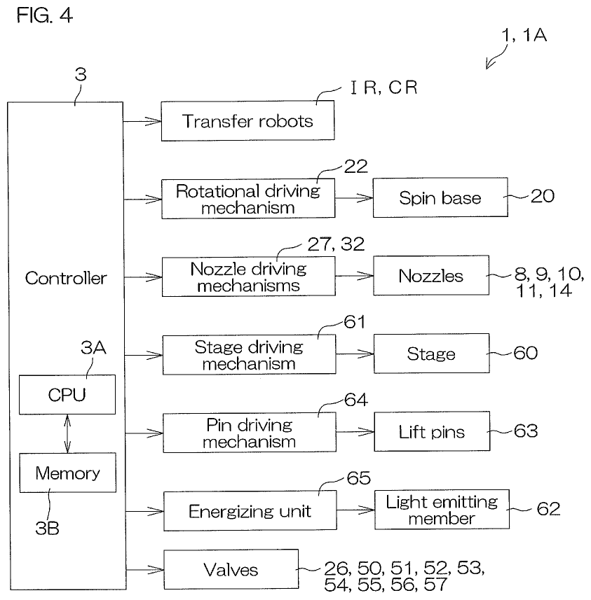

FIG. 4 is a block diagram for describing an electrical arrangement of the substrate processing apparatus 1. The controller 3 includes a microcomputer and, in accordance with a predetermined control program, controls control objects included in the substrate processing apparatus 1.

Specifically, the controller 3 includes a processor 3A (CPU) and a memory 3B in which the control program is stored. The controller 3 is arranged to execute various controls for substrate processing by the processor 3A executing the control program.

In particular, the controller 3 is programmed to control the first transfer robot IR, the second transfer robot CR, the rotational driving mechanism 22, the first nozzle driving mechanism 27, the stage driving mechanism 61, the pin driving mechanism 64, the energizing unit 65, the suction valve 26, the polymer-containing liquid valve 50, the first cleaning liquid valve 51, the rinse liquid valve 52, the removing liquid valve 53, the lower surface rinse liquid valve 54, etc.

Respective steps described below are executed by the controller 3 controlling the respective members included in the substrate processing apparatus 1. In other words, the controller 3 is programmed to execute the respective steps described below.

Also, although representative members are illustrated in FIG. 4, this does not mean that unillustrated members are not controlled by the controller 3 and the controller 3 can appropriately control respective members included in the substrate processing apparatus 1. Members described with respective modification examples and a second preferred embodiment described below are also indicated together in FIG. 4 and these members are also controlled by the controller 3.

### <Example of Substrate Processing>

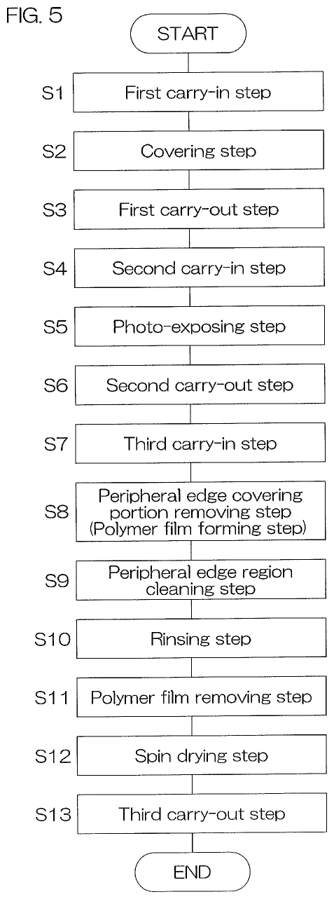

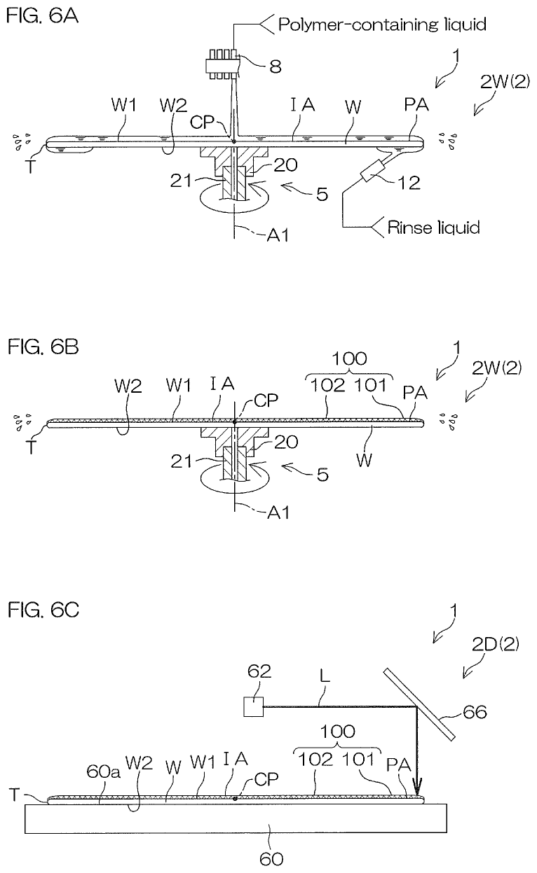

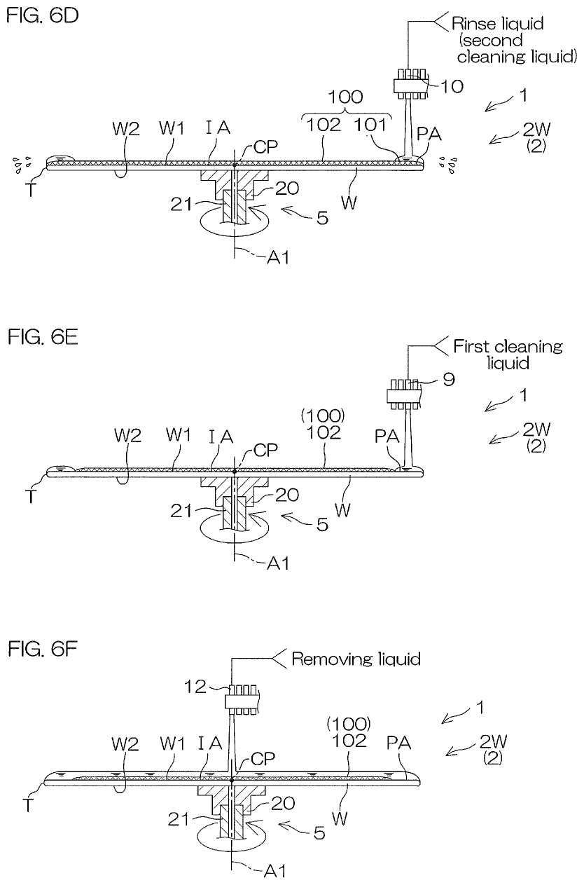

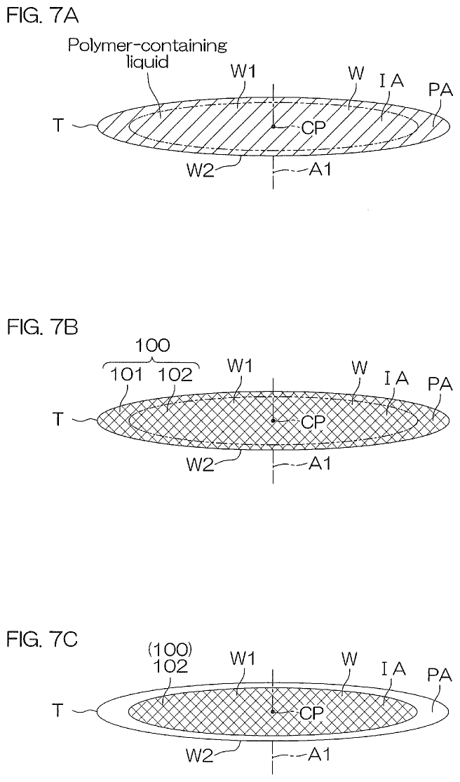

FIG. 5 is a flowchart for describing an example of substrate processing executed by the substrate processing apparatus 1. FIG. 6A to FIG. 6F are schematic views for describing conditions of the substrate W and its surroundings when the substrate processing is being performed. FIG. 7A to FIG. 7C are perspective views of the substrate W during the substrate processing.

In the substrate processing by the substrate processing apparatus 1, for example, as shown in FIG. 5, a first carry-in step (step S1), a covering step (step S2), a first carry-out step (step S3), a second carry-in step (step S4), a photo-exposing step (step S5), a second carry-out step (step S6), a third carry-in step (step S7), a peripheral edge covering portion removing step (step S8), a peripheral edge region cleaning step (step S9), a rinsing step (step S10), a polymer film removing step (step S11), a spin-drying step (step S12), and a third carry-out step (step S13) are executed. In the following, details of the substrate processing shall be described mainly with reference to FIG. 2, FIG. 3, and FIG. 5. FIG. 6A to FIG. 7C shall be referenced where appropriate.

First, an unprocessed substrate W is carried from a carrier C into a wet processing unit 2W by the first transfer robot IR and the second transfer robot CR (see FIG. 1) and transferred to the spin chuck 5 (first carry-in step: step S1). The substrate W is thereby held in the processing orientation by the spin chuck 5 (substrate holding step). At this point, the substrate W is held by the spin chuck 5 such that the first principal surface W1 is the upper surface. The spin chuck 5 starts rotation of the substrate W while holding the substrate W (substrate rotating step).

After the second transfer robot CR retreats from the chamber 4, the covering step (step S2) of forming a polymer film 100 (see FIG. 6B) that covers the peripheral edge region PA and the inner side region IA of the upper surface of the substrate W is executed.

Specifically, the first nozzle driving mechanism 27 moves the polymer-containing liquid nozzle 8 to a processing position. The processing position of the polymer-containing liquid nozzle 8 is, for example, the central position. The polymer-containing liquid valve 50 is opened in the state in which the polymer-containing liquid nozzle 8 is positioned at the processing position. Thereby, the polymer-containing liquid is supplied (discharged) from the polymer-containing liquid nozzle 8 toward the center portion CP (inner side region IA) of the upper surface of the substrate W as shown in FIG. 6A (polymer-containing liquid supplying step, polymer-containing liquid discharging step). The polymer-containing liquid nozzle 8 is an example of a polymer-containing liquid discharging member.

The polymer-containing liquid discharged from the polymer-containing liquid nozzle 8 lands on the center portion CP (inner side region IA) of the upper surface of the substrate W. The polymer-containing liquid on the substrate W spreads toward the peripheral edge T of the substrate W due to a centrifugal force due to the rotation of the substrate W. Thereby, an entirety of the upper surface of the substrate W becomes covered by the polymer-containing liquid as shown in FIG. 7A (covering step).

The rinse liquid is supplied to the lower surface of the substrate W while the polymer-containing liquid is supplied to the upper surface of the substrate W. In detail, the lower surface rinse liquid valve 54 is opened and the rinse liquid is discharged toward the lower surface of the substrate W from the lower surface rinse liquid nozzle 12. The rinse liquid on the lower surface of the substrate W moves toward the peripheral edge T of the substrate W and scatters outside the substrate W due to the centrifugal force. Since the peripheral edge region of the lower surface of the substrate W is protected by the rinse liquid, the polymer-containing liquid on the upper surface of the substrate W can be suppressed from flowing along the peripheral edge T of the substrate W and reaching the lower surface of the substrate W.

After the polymer-containing liquid has been supplied to the upper surface of the substrate W for a predetermined period, the polymer-containing liquid valve 50 is closed. The discharge of the polymer-containing liquid from the polymer-containing liquid nozzle 8 is thereby stopped.

At the same time that the discharge of the polymer-containing liquid is stopped or after the discharge of the polymer-containing liquid is stopped, the lower surface rinse liquid valve 54 is closed. By the lower surface rinse liquid valve 54 being closed, the discharge of the rinse liquid from the lower surface rinse liquid nozzle 12 is stopped. Thereby, the polymer-containing liquid on the upper surface of the substrate W can be suppressed from flowing along the peripheral edge T of the substrate W and reaching the lower surface of the substrate W after the discharge of the rinse liquid has been stopped.

After the discharge of the polymer-containing liquid is stopped, the rotation of the substrate W is continued such that a portion of the polymer-containing liquid on the substrate W scatters outside the substrate W from the peripheral edge T of the substrate W. A liquid film of the polymer-containing liquid on the substrate W is thereby thinned (spin-off step, film thinning step).

The centrifugal force due to the rotation of the substrate W acts not just on the polymer-containing liquid on the substrate W but also on a gas in contact with the polymer-containing liquid on the substrate W. Therefore, by the action of the centrifugal force, a radial gas stream by which the gas is directed toward the peripheral edge T of the substrate W is formed. By the gas stream, the solvent in a gas state in contact with the polymer-containing liquid on the substrate W is eliminated from an atmosphere in contact with the substrate W. Evaporation (volatilization) of the solvent from the polymer-containing liquid on the substrate W is thus promoted and the polymer film 100 is formed as shown in FIG. 6B (evaporation forming step). As shown in FIG. 7B, the polymer film 100 has a peripheral edge covering portion 101 of annular shape that covers the peripheral edge region PA of the upper surface of the substrate W and an inner side covering portion 102 of circular shape that covers the inner side region IA.

After the polymer film 100 is formed, the rotation of the substrate W is stopped. Thereafter, the second transfer robot CR enters into the wet processing unit 2W, receives the processed substrate W from the spin chuck 5, and carries it outside the wet processing unit 2W (first carry-out step: step S3).

Thereafter, the substrate W is carried into the dry processing unit 2D and transferred to the plurality of lift pins 63 by the second transfer robot CR (second carry-in step: step S4). Thereafter, by the plurality of lift pins 63 being moved to the lower position by the pin driving mechanism 64, the substrate W is placed on the mounting surface 60a of the stage 60. At this point, the substrate W is placed on the mounting surface 60a such that the first principal surface W1 is the upper surface.

In the state where the substrate W is placed on the mounting surface 60a, electric power is supplied from the energizing unit 65 to the light emitting member 62 such that the light L is emitted from the light emitting member 62 as shown in FIG. 6C. The peripheral edge covering portion 101 of the polymer film 100 is selectively photo-exposed by the light L emitted from the light emitting member 62 (photo-exposing step: step S5). By the photo-exposure, the polymer (photoresist) that constitutes the peripheral edge covering portion 101 is altered and the peripheral edge covering portion 101 becomes more easily dissolved in the rinse liquid than the inner side covering portion 102.

After the peripheral edge covering portion 101 is photo-exposed, the pin driving mechanism 64 moves the plurality of lift pins 63 to the upper position such that the plurality of lift pins 63 lift the substrate W from the mounting surface 60a of the stage 60. The second transfer robot CR receives the substrate W from the plurality of lift pins 63 and carries the substrate W outside the dry processing unit 2D (second carry-out step: step S6).

The substrate W carried out from the dry processing unit 2D is carried into the wet processing unit 2W and transferred to the spin chuck 5 by the second transfer robot CR (third carry-in step: step S7). The substrate W is thereby held in the processing orientation by the spin chuck 5 (substrate holding step). At this point, the substrate W is held by the spin chuck 5 such that the first principal surface W1 is the upper surface. The spin chuck 5 starts rotation of the substrate W while holding the substrate W (substrate rotating step).

After the second transfer robot CR retreats from the chamber 4, the peripheral edge covering portion removing step (step S8) of removing the peripheral edge covering portion 101 of the polymer film 100 is executed.

Specifically, the first nozzle driving mechanism 27 moves the rinse liquid nozzle 10 to the peripheral edge position. In the state where the rinse liquid nozzle 10 is positioned at the peripheral edge position, the rinse liquid valve 52 is opened. Thereby, the rinse liquid as the second cleaning liquid is supplied (discharged) from the rinse liquid nozzle 10 toward the peripheral edge region PA of the upper surface of the substrate W as shown in FIG. 6D (second cleaning liquid supplying step, second cleaning liquid discharging step).

The rinse liquid discharged from the rinse liquid nozzle 10 lands on the peripheral edge region PA of the upper surface of the substrate W. The rinse liquid that landed on the upper surface of the substrate W moves toward the peripheral edge T of the substrate W and is expelled out of the substrate W from the peripheral edge T of the substrate W due to the centrifugal force due to the rotation of the substrate W.

The peripheral edge covering portion 101 of the polymer film 100 is dissolved by the rinse liquid and is expelled from the upper surface of the substrate W together with the rinse liquid with the peripheral edge covering portion 101 dissolved therein. Not all of the peripheral edge covering portion 101 needs to be dissolved in the rinse liquid and a portion of the peripheral edge covering portion 101 may be expelled outside the substrate W upon being peeled from the upper surface of the substrate W by a liquid stream of the rinse liquid. By the peripheral edge covering portion 101 of the polymer film 100 being removed, the peripheral edge region PA of the upper surface of the substrate W is selectively exposed (peripheral edge exposing step). The rinse liquid nozzle 10 thus functions as a second cleaning liquid discharging member.

Here, as shown in FIG. 7C, even after the peripheral edge exposing step, the inner side region IA of the upper surface of the substrate W is covered by the inner side covering portion 102 of the polymer film 100. In other words, the inner side region IA of the upper surface of the substrate W is protected by the inner side covering portion 102 of the polymer film 100. The inner side covering portion 102 functions as a protective film. The polymer film 100 that exposes the peripheral edge region PA and covers the inner side region IA is thus formed by execution of the peripheral edge covering portion removing step (polymer film forming step).

After the rinse liquid has been supplied for a predetermined period, the peripheral edge region cleaning step (step S9) of cleaning the peripheral edge region PA of the upper surface of the substrate W is executed.

Specifically, by closing the rinse liquid valve 52, the discharge of the rinse liquid from the rinse liquid nozzle 10 is stopped. After the discharge of the rinse liquid is stopped, the first nozzle driving mechanism 27 moves the first cleaning liquid nozzle 9 to the peripheral edge position. In the state where the first cleaning liquid nozzle 9 is positioned at the peripheral edge position, the first cleaning liquid valve 51 is opened. Thereby, the first cleaning liquid is supplied (discharged) from the first cleaning liquid nozzle 9 toward the peripheral edge region PA of the upper surface of the substrate W as shown in FIG. 6E (first cleaning liquid supplying step, first cleaning liquid discharging step). The first cleaning liquid nozzle 9 is an example of a first cleaning liquid discharging member.

The first cleaning liquid discharged from the first cleaning liquid nozzle 9 lands on the peripheral edge region PA of the upper surface of the substrate W. The first cleaning liquid that landed on the upper surface of the substrate W moves toward the peripheral edge T of the substrate W and is expelled out of the substrate W from the peripheral edge T of the substrate W due to the centrifugal force due to the rotation of the substrate W. By the first cleaning liquid, the removal objects on the peripheral edge region PA are removed and the peripheral edge region PA is cleaned.

After the first cleaning liquid has been supplied for a predetermined period, the rinsing step (step S10) of supplying the rinse liquid to the peripheral edge region PA of the upper surface of the substrate W and rinsing the peripheral edge region PA of the upper surface of the substrate W is executed.

Specifically, the first cleaning liquid valve 51 is closed and the discharge of the first cleaning liquid from the first cleaning liquid nozzle 9 is stopped. After the discharge of the first cleaning liquid is stopped, the first nozzle driving mechanism 27 moves the rinse liquid nozzle 10 to the peripheral edge position. In the state where the rinse liquid nozzle 10 is positioned at the peripheral edge position, the rinse liquid valve 52 is opened. Thereby, the rinse liquid is supplied (discharged) from the rinse liquid nozzle 10 toward the peripheral edge region PA of the upper surface of the substrate W (rinse liquid supplying step, rinse liquid discharging step).

The rinse liquid discharged from the rinse liquid nozzle 10 lands on the peripheral edge region PA of the upper surface of the substrate W. The rinse liquid that landed on the upper surface of the substrate W spreads toward the peripheral edge T of the substrate W and is expelled outside the substrate W by an action of the centrifugal force. The rinse liquid is eliminated from the upper surface of the substrate W together with the first cleaning liquid that was attached to the substrate W at the start of supplying of the rinse liquid. The upper surface of the substrate W is thereby rinsed.

After the rinse liquid has been supplied for a predetermined period, the polymer film removing step (step S11) of supplying the removing liquid to the inner side region IA of the upper surface of the substrate W and removing the polymer film 100 from the upper surface of the substrate W is executed.

Specifically, by closing the rinse liquid valve 52, the discharge of the rinse liquid from the rinse liquid nozzle 10 is stopped. After the discharge of the rinse liquid is stopped, the first nozzle driving mechanism 27 moves the removing liquid nozzle 11 to the central position. In the state where the removing liquid nozzle 11 is positioned at the central position, the removing liquid valve 53 is opened. Thereby, the removing liquid is discharged from the removing liquid nozzle 11 toward the inner side region IA of the upper surface of the substrate W as shown in FIG. 6F (removing liquid supplying step, removing liquid discharging step).

The removing liquid discharged from the removing liquid nozzle 11 lands on a front surface of the polymer film 100 on the upper surface of the substrate W. The removing liquid that landed on the front surface of the polymer film 100 spreads radially toward the peripheral edge T of the substrate W due to an action of the centrifugal force. The removing liquid is expelled out of the substrate W from the peripheral edge T of the substrate W.

The inner side covering portion 102 of the polymer film 100 is dissolved by the removing liquid and is expelled from the upper surface of the substrate W together with the removing liquid. Not all of the inner side covering portion 102 needs to be dissolved in the removing liquid and a portion of the inner side covering portion 102 may be expelled from the upper surface of the substrate W upon being peeled from the upper surface of the substrate W by a liquid stream of the removing liquid. By the inner side covering portion 102 of the polymer film 100 being removed, the polymer film 100 is removed from the entirety of the upper surface of the substrate W.

Next, the spin-drying step (step S12) of drying the upper surface of the substrate W by rotating the substrate W at high speed is executed. Specifically, the removing liquid valve 53 is closed to stop the supply of the removing liquid to the upper surface of the substrate W and the first nozzle driving mechanism 27 makes the removing liquid nozzle 11 retreat to the retreat position. The spin chuck 5 then accelerates the rotation of the substrate W and rotates the substrate W at a high speed (for example, of 1500 rpm). Thereby, a large centrifugal force acts on the removing liquid attached to the substrate W and the removing liquid is spun off to a periphery of the substrate W.

After the spin-drying step (step S12), the spin chuck 5 stops the rotation of the substrate W. Thereafter, the second transfer robot CR enters into the wet processing unit 2W, receives the processed substrate W from the spin chuck 5, and carries it outside the wet processing unit 2W (third carry-out step: step S13). The substrate W is transferred from the second transfer robot CR to the first transfer robot IR and housed in a carrier C by the first transfer robot IR.

### <Changes in the Peripheral Edge Region of the Upper Surface of the Substrate During the Substrate Processing>

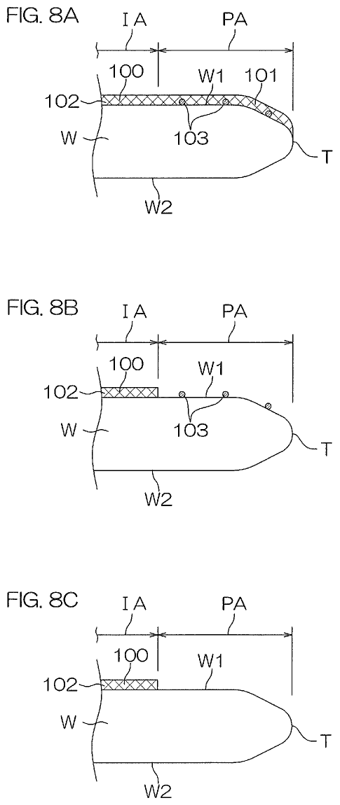

FIG. 8A to FIG. 8C are schematic views for describing changes in the peripheral edge region PA of the upper surface of the substrate W during the substrate processing.

FIG. 8A shows a state immediately after the polymer film 100 is formed on the upper surface of the substrate W. As mentioned above, removal objects 103 are attached at times to the peripheral edge region PA of the upper surface of the substrate W.

The entirety of the upper surface of the substrate W is covered by the polymer film 100. The removal objects 103 are thus also covered by the peripheral edge covering portion 101 of the polymer film 100.

FIG. 8B shows a state where the peripheral edge covering portion 101 of the polymer film 100 is removed selectively by the rinse liquid as the second cleaning liquid and the inner side covering portion 102 remains. By the peripheral edge covering portion 101 being removed, the removal objects 103 are exposed together with the peripheral edge region PA of the upper surface of the substrate W. Here, in FIG. 8B, illustration of the rinse liquid is omitted for convenience of description.

FIG. 8C shows a state after the peripheral edge region PA is cleaned by the first cleaning liquid. As shown in FIG. 8C, the removal objects 103 are removed by the first cleaning liquid. Here, in FIG. 8C, illustration of the first cleaning liquid is omitted for convenience of description.

### Summary of the First Preferred Embodiment

According to the first preferred embodiment, the polymer film forming step of forming the polymer film 100 that exposes the peripheral edge region PA of the upper surface (first principal surface W1) of the substrate W and covers the inner side region IA of the upper surface (first principal surface W1) of the substrate W is executed. Thereafter, the first cleaning liquid is supplied to the peripheral edge region PA such that the inner side covering portion 102 of the polymer film 100 is maintained on the upper surface of the substrate W and further thereafter, the removing liquid is supplied to the entirety of the upper surface of the substrate W.

Therefore, after cleaning the peripheral edge region PA with the cleaning liquid that is comparatively unlikely to dissolve the polymer film 100 and removing the removal objects 103 from the peripheral edge region PA, the inner side covering portion 102 can be removed from the upper surface by the removing liquid that dissolves the polymer film 100 comparatively easily.

Consequently, the peripheral edge region PA can be cleaned while suppressing contamination of the inner side region IA. Thereby, attachment of the removal objects 103 to the uneven pattern in the inner side region IA of the upper surface (first principal surface W1) that is the device surface can be suppressed.

According to the first preferred embodiment, the inner side region IA is protected by the polymer film 100. Unlike a liquid film, the polymer film 100 of semisolid state or solid state is maintained in shape on the upper surface of the substrate W and practically does not spread in covering range. The upper surface of the substrate W is thus easily exposed in an annular region corresponding to an appropriate distance from the peripheral edge T of the substrate W. Thus, in comparison to a case of protecting the inner side region IA with a liquid, the inner side region IA can be protected by the polymer film 100 in a state of appropriately exposing the peripheral edge region PA.

According to the first preferred embodiment, after forming the polymer film 100 having the peripheral edge covering portion 101 and the inner side covering portion 102, the peripheral edge region PA of the upper surface of the substrate W is exposed by selectively removing the peripheral edge covering portion 101. That is, after forming the polymer film 100 across a wide range on the substrate W, the inner side region IA can be covered selectively by the polymer film 100 by removing an unnecessary portion.

Forming the polymer film 100 that exposes the peripheral edge region PA and covers the inner side region IA while suppressing the spread of the polymer-containing liquid from the inner side region IA to the peripheral edge region PA is not impossible but is difficult.

On the other hand, there is no such difficulty if, as in the first preferred embodiment, the unnecessary portion (peripheral edge covering portion 101) is selectively removed after forming the polymer film 100 across the wide range on the substrate W. That is, there is no need to suppress the spread of the polymer-containing liquid on the substrate W and it is thus easy to control a region of the upper surface of the substrate W covered by the polymer film 100.

In the first preferred embodiment, the peripheral edge covering portion 101 is made by selective photo-exposure to be more easily dissolved in the rinse liquid as the second cleaning liquid than the inner side covering portion 102. After the photo-exposing step (step S5), the rinse liquid is discharged toward the peripheral edge region PA. The peripheral edge covering portion 101 can thus be removed from the upper surface of the substrate W while maintaining the inner side covering portion 102 on the inner side region IA.

Also, the peripheral edge covering portion 101 that is removed by the rinse liquid is the portion of the polymer film 100 that is photo-exposed. Since the portion of the polymer film 100 that has been photo-exposed can thus be removed selectively regardless of a degree of spread of the rinse liquid, a removal portion can be demarcated with high precision. The peripheral edge covering portion 101 can thus be removed with high precision in comparison to a case of removing the peripheral edge covering portion 101 using a liquid such as a removing liquid, etc.

The polymer contained in the polymer-containing liquid may be a photoresist of negative type. In this case, by selectively photo-exposing an entirety of the inner side covering portion 102 of the polymer film 100 in the photo-exposing step (step S5), just the peripheral edge covering portion 101 can be removed by the rinse liquid while maintaining the inner side covering portion 102 on the inner side region IA in the subsequent peripheral edge covering portion removing step (step S8).

### <Modification Examples of the Peripheral Edge Covering Portion Removing Step>

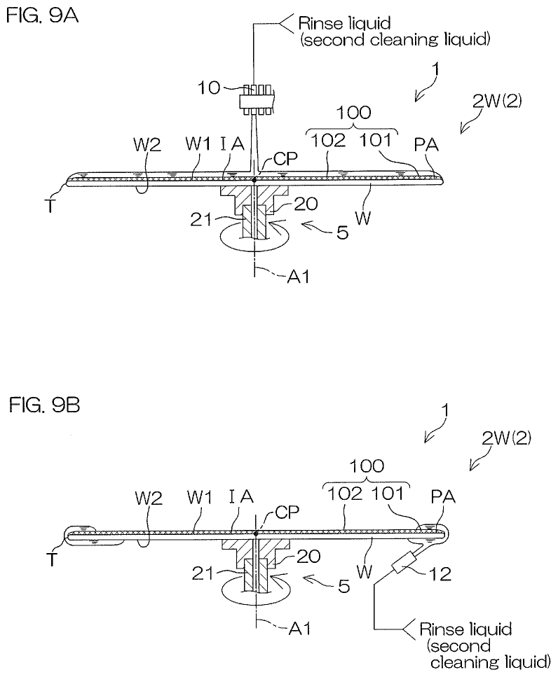

Respective modification examples described below can be applied to the peripheral edge covering portion removing step (step S8). FIG. 9A is a schematic view for describing a first modification example of the peripheral edge covering portion removing step. Unlike in the first preferred embodiment, the rinse liquid (second cleaning liquid) may be discharged from the rinse liquid nozzle 10 (second cleaning liquid discharging member) toward the inner side region IA of the upper surface of the substrate W in the peripheral edge covering portion removing step (step S8) as shown in FIG. 9A.

By doing so, the peripheral edge covering portion 101 can be removed from the upper surface of the substrate W while protecting the inner side covering portion 102 by the rinse liquid as the second cleaning liquid. Also, the rinse liquid discharged toward the inner side region IA lands on the front surface of the polymer film 100. The rinse liquid that landed on the front surface of the polymer film 100 spreads radially on the polymer film 100 and is expelled outside the substrate W through the peripheral edge region PA while selectively dissolving the peripheral edge covering portion 101. By the peripheral edge covering portion 101 of the polymer film 100 being removed selectively, the peripheral edge region PA of the upper surface of the substrate W is exposed (peripheral edge exposing step).

If the rinse liquid is made to land on the peripheral edge covering portion 101, the rinse liquid is expelled outside the substrate W immediately while dissolving the peripheral edge covering portion 101 in a vicinity of the liquid landing point without spreading across an entirety of the peripheral edge region PA. On the other hand, when the rinse liquid is made to land on a front surface of the peripheral edge covering portion 101 as shown in FIG. 9A, the radially spreading rinse liquid spreads across the peripheral edge region PA of a wide range and the peripheral edge covering portion 101 can thus be removed efficiently.

FIG. 9B is a schematic view for describing a second modification example of the peripheral edge covering portion removing step. As shown in FIG. 9B, it is also possible to use the rinse liquid that is discharged from the lower surface rinse liquid nozzle 12 as the second cleaning liquid.

Specifically, the rinse liquid discharged from the lower surface rinse liquid nozzle 12 lands on the peripheral edge region of the lower surface of the substrate W. The rinse liquid that landed on the lower surface of the substrate W spreads toward the peripheral edge T of the substrate W due to the centrifugal force due to the rotation of the substrate W. At least a portion of the rinse liquid flows along the peripheral edge T of the substrate W and is supplied to the peripheral edge region PA (peripheral edge rinse liquid supplying step, peripheral edge second cleaning liquid supplying step). The rinse liquid that flows along the peripheral edge T of the substrate W and is supplied to the peripheral edge region PA is expelled outside the substrate W from the peripheral edge T of the substrate W.

The peripheral edge covering portion 101 of the polymer film 100 is dissolved in the rinse liquid and is expelled from the upper surface of the substrate W together with the rinse liquid with the peripheral edge covering portion 101 dissolved therein. By the peripheral edge covering portion 101 of the polymer film 100 thus being removed selectively, the peripheral edge region PA of the upper surface of the substrate W is exposed (peripheral edge exposing step).

### <Substrate Processing Apparatus According to a Second Preferred Embodiment>

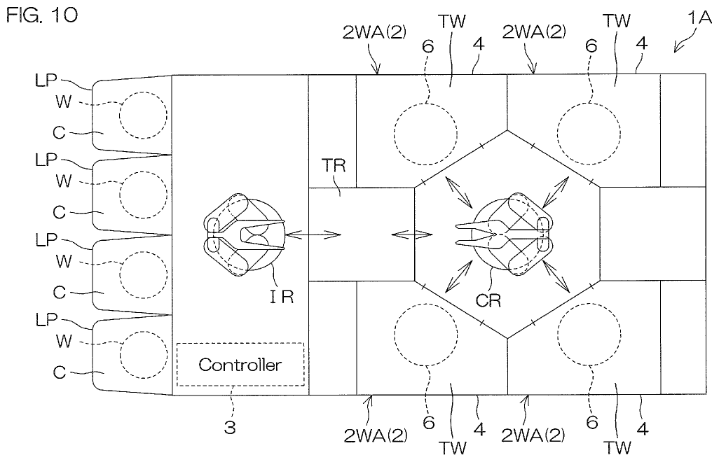

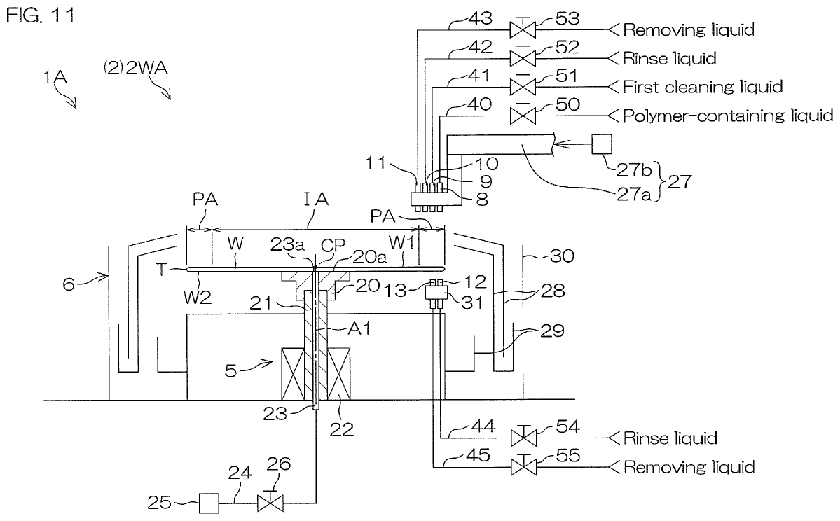

FIG. 10 is a plan view for describing an arrangement example of a substrate processing apparatus 1A according to a second preferred embodiment of the present invention. In FIG. 10, arrangements equivalent to arrangements shown in FIG. 1 to FIG. 9B described above shall be provided with the same reference signs as in FIG. 1, etc., and description thereof shall be omitted. The same applies to FIG. 11 to FIG. 18C to be described below.

A main point of difference of the substrate processing apparatus 1A according to the second preferred embodiment with respect to the substrate processing apparatus 1 according to the first preferred embodiment is the point that the substrate processing apparatus 1A is not provided with the dry processing unit 2D. In the second preferred embodiment, each processing tower TW is constituted of a plurality of wet processing units 2WA.

The polymer contained in the polymer-containing liquid used in the wet processing units 2WA do not need to be altered by light irradiation and suffices to be a polymer with which a solubility in the first cleaning liquid is lower than a solubility in the removing liquid. Specifically, the polymer may contain at least one type among polystyrene, polysulfonic acid, and novolac.

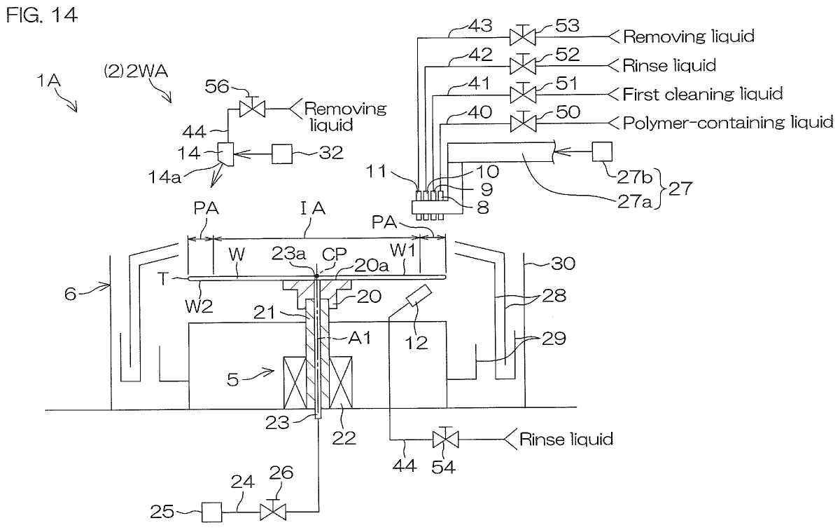

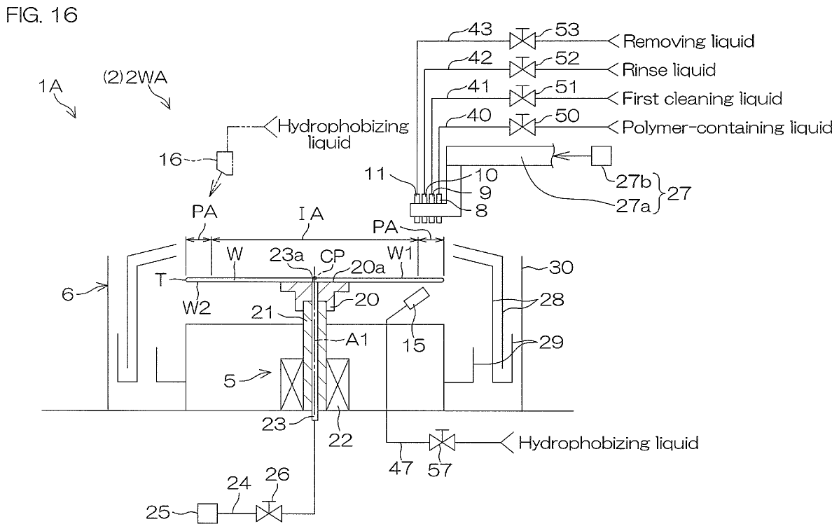

The wet processing units 2WA have, for example, an arrangement of a first example to a third example respectively shown in FIG. 11, FIG. 14, and FIG. 16 described below.

### <Arrangement of the First Example of the Wet Processing Unit According to the Second Preferred Embodiment>

FIG. 11 is a schematic view for describing the arrangement of the first example of the wet processing unit 2WA according to the second preferred embodiment.

A main point of difference of the first example of the wet processing unit 2WA according to the second preferred embodiment with respect to the wet processing unit 2W according to the first preferred embodiment is the point that a lower surface removing liquid nozzle 13 that discharges a removing liquid toward the lower surface (second principal surface W2) of the substrate W is provided. The lower surface removing liquid nozzle 13 is an example of a removing liquid discharging member.

As the removing liquid discharged from the lower surface removing liquid nozzle 13, a liquid listed as the removing liquid discharged from the removing liquid nozzle 11 can be used.

The lower surface removing liquid nozzle 13 is connected to a lower surface removing liquid piping 45 that guides the removing liquid to the lower surface removing liquid nozzle 13. The lower surface removing liquid piping 45 is provided with a lower surface removing liquid valve 55 that opens/closes the lower surface removing liquid piping 45.

The lower surface removing liquid nozzle 13 has a discharge port directed toward the peripheral edge region of the lower surface of the substrate W. When the lower surface removing liquid valve 55 is opened, a continuous stream of the removing liquid is discharged from the lower surface removing liquid nozzle 13 toward the peripheral edge region of the lower surface. The lower surface removing liquid nozzle 13 suffices to supply the removing liquid to the lower surface of the substrate W and does not necessarily have to discharge the removing liquid toward the peripheral edge region of the lower surface of the substrate W.

The lower surface removing liquid nozzle 13 and the lower surface rinse liquid nozzle 12 may be supported in common by a single holder 31. The holder 31 may be fixed in position with respect to the spin chuck 5 or may be movable in a direction along the lower surface of the substrate W.

### <First Example of Substrate Processing According to the Second Preferred Embodiment>

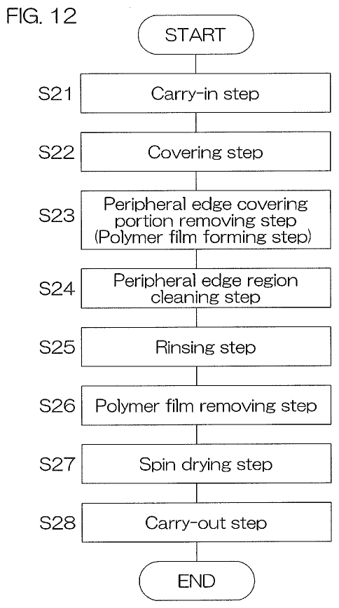

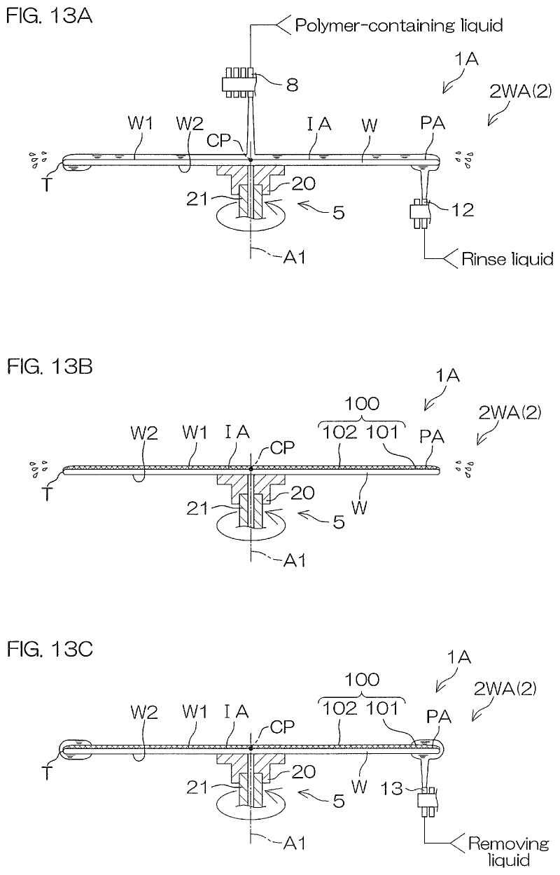

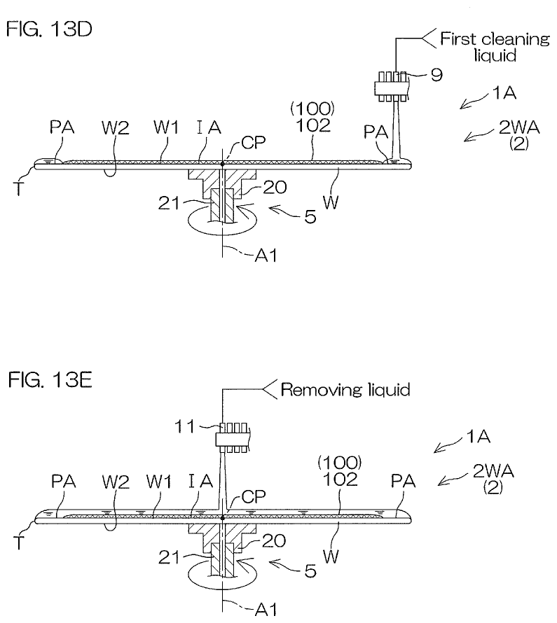

FIG. 12 is a flowchart for describing a first example of substrate processing executed by the substrate processing apparatus 1A. FIG. 13A to FIG. 13E are schematic views for describing conditions of the substrate W and its surroundings when the first example of substrate processing is being performed by the substrate processing apparatus 1A.

In the first example of substrate processing according to the second preferred embodiment, for example, as shown in FIG. 12, a carry-in step (step S21), a covering step (step S22), a peripheral edge covering portion removing step (step S23), a peripheral edge region cleaning step (step S24), a rinsing step (step S25), a polymer film removing step (step S26), a spin-drying step (step S27), and a carry-out step (step S28) are executed.

In the following, details of the first example of substrate processing according to the second preferred embodiment shall be described mainly with reference to FIG. 11 and FIG. 12. FIG. 13A to FIG. 13E shall be referenced where appropriate.

First, an unprocessed substrate W is carried from a carrier C into a wet processing unit 2WA by the first transfer robot IR and the second transfer robot CR (see FIG. 10) and transferred to the spin chuck 5 (carry-in step: step S21). The substrate W is thereby held in the processing orientation by the spin chuck 5 (substrate holding step). At this point, the substrate W is held by the spin chuck 5 such that the first principal surface W1 is the upper surface. The substrate W continues to be held by the spin chuck 5 until the spin-drying step (step S27) ends. The spin chuck 5 starts rotation of the substrate W while holding the substrate W (substrate rotating step).

After the second transfer robot CR retreats from the chamber 4, the covering step (step S22) of forming the polymer film 100 that covers the peripheral edge region PA and the inner side region IA of the upper surface of the substrate W is executed as shown in FIG. 13A and FIG. 13B. Details of the covering step (step S22) are the same as those of the covering step (step S2) of the substrate processing according to the first preferred embodiment and therefore, description thereof shall be omitted.

After the polymer film 100 is formed, the peripheral edge covering portion removing step (step S23) of removing the peripheral edge covering portion 101 of the polymer film 100 is executed.

Specifically, the lower surface removing liquid valve 55 is opened. Thereby, the removing liquid is discharged from the lower surface removing liquid nozzle 13 toward the peripheral edge region of the lower surface (second principal surface W2) of the substrate W as shown in FIG. 13C (second principal surface removing liquid discharging step).

The removing liquid discharged from the lower surface removing liquid nozzle 13 lands on the peripheral edge region of the lower surface of the substrate W. The removing liquid that landed on the lower surface of the substrate W spreads toward the peripheral edge T of the substrate W due to the centrifugal force due to the rotation of the substrate W. At least a portion of the removing liquid flows along the peripheral edge T of the substrate W and is supplied to the peripheral edge region PA (peripheral edge removing liquid supplying step). The removing liquid that flows along the peripheral edge T of the substrate W and is supplied to the peripheral edge region PA is expelled outside the substrate W from the peripheral edge T of the substrate W.

By the removing liquid being supplied to the peripheral edge region PA, the peripheral edge covering portion 101 of the polymer film 100 is selectively removed from the peripheral edge region PA of the upper surface of the substrate W. In detail, the peripheral edge covering portion 101 is dissolved in the removing liquid and the removing liquid with the peripheral edge covering portion 101 dissolved therein is expelled from the upper surface of the substrate W. Not all of the peripheral edge covering portion 101 needs to be dissolved in the removing liquid and a portion of the peripheral edge covering portion 101 may be expelled from the upper surface of the substrate W upon being peeled from the upper surface of the substrate W by a liquid stream of the removing liquid. By the peripheral edge covering portion 101 of the polymer film 100 being removed, the peripheral edge region PA of the upper surface of the substrate W is exposed (peripheral edge exposing step).

Here, even after the peripheral edge exposing step, the inner side region IA of the upper surface of the substrate W is covered by the inner side covering portion 102 of the polymer film 100. The inner side region IA of the upper surface of the substrate W is protected by the inner side covering portion 102 of the polymer film 100. The inner side covering portion 102 functions as a protective film. The polymer film 100 that exposes the peripheral edge region PA and covers the inner side region IA is thus formed by execution of the peripheral edge covering portion removing step (polymer film forming step).

After the removing liquid has been supplied for a predetermined period, the lower surface removing liquid valve 55 is closed and the discharge of the removing liquid from the lower surface removing liquid nozzle 13 is stopped. After the discharge of the removing liquid is stopped, the peripheral edge region cleaning step (step S24) shown in FIG. 13D, the rinsing step (step S25), and the polymer film removing step (step S26) shown in FIG. 13E are executed. The peripheral edge region cleaning step (step S24), the rinsing step (step S25), and the polymer film removing step (step S26) are respectively the same as the peripheral edge region cleaning step (step S9), the rinsing step (step S10), and the polymer film removing step (step S11) of the substrate processing according to the first preferred embodiment and therefore, description of these shall be omitted.

Next, the spin-drying step (step S27) of drying the upper surface of the substrate W by rotating the substrate W at high speed is executed. Specifically, the removing liquid valve 53 is closed to stop the supply of the removing liquid to the upper surface of the substrate W and the first nozzle driving mechanism 27 makes the removing liquid nozzle 11 retreat to the retreat position. The spin chuck 5 then accelerates the rotation of the substrate W and rotates the substrate W at a high speed (for example, of 1500 rpm). Thereby, a large centrifugal force acts on the removing liquid attached to the substrate W and the removing liquid is spun off to the periphery of the substrate W.

After the spin-drying step (step S27), the spin chuck 5 stops the rotation of the substrate W. Thereafter, the second transfer robot CR enters into the wet processing unit 2WA, receives the processed substrate W from the spin chuck 5, and carries it outside the wet processing unit 2WA (carry-out step: step S28). The substrate W is transferred from the second transfer robot CR to the first transfer robot IR and housed in a carrier C by the first transfer robot IR.

When the wet processing unit 2WA has the arrangement of the first example shown in FIG. 11, the following effect is exhibited in addition to the same effects as the substrate processing apparatus 1 according to the first preferred embodiment.

Specifically, the removing liquid discharged from the lower surface removing liquid nozzle 13 can be supplied to the peripheral edge region PA without letting it reach the inner side region IA. The peripheral edge covering portion 101 can thereby be removed selectively.

### <Arrangement of the Second Example of the Wet Processing Unit According to the Second Preferred Embodiment>

FIG. 14 is a schematic view for describing the arrangement of the second example of the wet processing unit 2WA according to the second preferred embodiment. A main point of difference of the second example of the wet processing unit 2WA according to the second preferred embodiment with respect to the wet processing unit 2W according to the first preferred embodiment is the point that an inclined removing liquid nozzle 14 that discharges a removing liquid toward the peripheral edge region PA of the upper surface (first principal surface W1) of the substrate W obliquely with respect to the upper surface of the substrate W is provided. The inclined removing liquid nozzle 14 faces the inner side region IA of the upper surface of the substrate W. The inclined removing liquid nozzle 14 is an example of the removing liquid discharging member.

As the removing liquid discharged from the inclined removing liquid nozzle 14, a liquid listed as the removing liquid discharged from the removing liquid nozzle 11 can be used.

The inclined removing liquid nozzle 14 has an inclined discharge port 14a that discharges the removing liquid in a direction inclined with respect to the upper surface, that is, an inclined direction with respect to the horizontal direction. More specifically, the inclined discharge port 14a is inclined in a direction of separating from the center portion CP (rotational axis A1) as the upper surface of the substrate W is approached.

The inclined removing liquid nozzle 14 is connected to an inclined removing liquid piping 46 that guides the removing liquid to the inclined removing liquid nozzle 14. The inclined removing liquid piping 46 is provided with an inclined removing liquid valve 56 that opens/closes the inclined removing liquid piping 46. When the inclined removing liquid valve 56 is opened, the removing liquid of a continuous stream is discharged from the inclined removing liquid nozzle 14.

The inclined removing liquid nozzle 14 is moved integrally in a direction (horizontal direction) along the upper surface of the substrate W by a second nozzle driving mechanism 32. The second nozzle driving mechanism 32 can move the inclined removing liquid nozzle 14 between a central position and a retreat position. The second nozzle driving mechanism 32 can also position the inclined removing liquid nozzle 14 at a peripheral edge position.

The second nozzle driving mechanism 32 includes an arm (not shown) that supports the inclined removing liquid nozzle 14 and an arm driving mechanism (not shown) that moves the arm in the direction (horizontal direction) along the upper surface of the substrate W. The arm driving mechanism includes an actuator such as an electric motor, an air cylinder, etc.

The arm driving mechanism may be a pivoting type driving mechanism that pivots the arm around a predetermined pivoting axis or may be a linear driving mechanism that moves the arm rectilinearly in a direction in which the arm extends. The inclined removing liquid nozzle 14 (more specifically, the arm that supports the inclined removing liquid nozzle 14) may also be arranged such as to be movable in a vertical direction by the arm driving mechanism.

### <Second Example of Substrate Processing According to the Second Preferred Embodiment>

The second example of the wet processing unit 2WA according to the second preferred embodiment is capable of executing the same substrate processing as the first example of substrate processing according to the second preferred embodiment shown in FIG. 12. However, a method for removing the peripheral edge covering portion 101 in the peripheral edge covering portion removing step (S23) differs.

Specifically, in the peripheral edge covering portion removing step (S23), first, the inclined removing liquid nozzle 14 is moved to the peripheral edge position by the second nozzle driving mechanism 32.

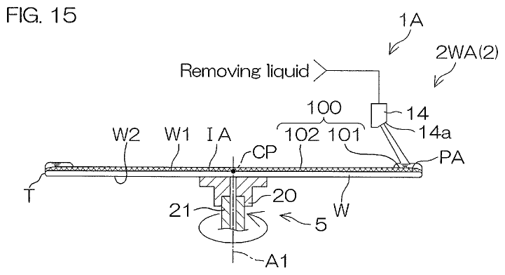

In the state where the inclined removing liquid nozzle 14 is positioned at the peripheral edge position, the inclined removing liquid valve 56 is opened. Thereby, the removing liquid is discharged from the inclined removing liquid nozzle 14 toward the peripheral edge region PA of the upper surface (first principal surface W1) of the substrate W as shown in FIG. 15 (inclined removing liquid discharging step).

The removing liquid discharged from the inclined removing liquid nozzle 14 lands on the peripheral edge region PA of the upper surface of the substrate W. The removing liquid that landed on the peripheral edge region PA moves toward the peripheral edge T of the substrate W and is expelled outside the substrate W from the peripheral edge T of the substrate W due to the centrifugal force due to the rotation of the substrate W.

The peripheral edge covering portion 101 of the polymer film 100 is thus removed from the peripheral edge region PA of the upper surface of the substrate W. In detail, the peripheral edge covering portion 101 is dissolved in the removing liquid and the removing liquid with the peripheral edge covering portion 101 dissolved therein is expelled from the upper surface of the substrate W. Not all of the peripheral edge covering portion 101 needs to be dissolved in the removing liquid and a portion of the peripheral edge covering portion 101 may be expelled from the upper surface of the substrate W upon being peeled from the upper surface of the substrate W by a liquid stream of the removing liquid.

By the peripheral edge covering portion 101 of the polymer film 100 being removed selectively, the peripheral edge region PA of the upper surface of the substrate W is exposed (peripheral edge exposing step). The polymer film 100 that exposes the peripheral edge region PA and covers the inner side region IA is formed by execution of the peripheral edge covering portion removing step (step S23) (polymer film forming step).

When the wet processing unit 2WA has the arrangement of the second example shown in FIG. 14, the following effect is exhibited in addition to the same effects as the substrate processing apparatus 1 according to the first preferred embodiment.

Specifically, the removing liquid is discharged from the inclined removing liquid nozzle 14 toward the peripheral edge region PA obliquely with respect to the upper surface of the substrate W, that is, toward a direction of separating from the inner side region IA. The removing liquid can thus be supplied to the peripheral edge covering portion 101 that covers the peripheral edge region PA while suppressing the removing liquid from flowing to the inner side region IA. The removing liquid can thus be supplied directly from the inclined removing liquid nozzle 14 to the peripheral edge region PA without making a removing liquid supplied to the lower surface of the substrate W flow along the peripheral edge T of the substrate W. The peripheral edge covering portion 101 can be removed with high precision in comparison to a case of supplying the removing liquid from the lower surface to the peripheral edge region PA of the upper surface by making it flow along the peripheral edge T of the substrate W.

<Arrangement of the Third Example of the Wet Processing Unit According to the Second Preferred Embodiment>

FIG. 16 is a schematic view for describing the arrangement of the third example of the wet processing unit 2WA according to the second preferred embodiment. A main point of difference of the third example of the wet processing unit 2WA according to the second preferred embodiment with respect to the wet processing unit 2W according to the first preferred embodiment is the point that, in place of the lower surface rinse liquid nozzle 12, a lower surface hydrophobizing liquid nozzle 15 that discharges a hydrophobizing liquid toward the peripheral edge region of the lower surface of the substrate W is provided. The lower surface hydrophobizing liquid nozzle 15 is an example of a hydrophobizing liquid discharging member.

The hydrophobizing liquid discharged from the lower surface hydrophobizing liquid nozzle 15 is a liquid that increases a contact angle of the lower surface of the substrate W with respect to pure water. By hydrophobization, the contact angle of the principal surfaces of the substrate W increases, for example, to not less than 90°.

As the hydrophobizing liquid, for example, a silicon-based hydrophobizing liquid that hydrophobizes silicon itself and compounds containing silicon or a metal-based hydrophobizing liquid that hydrophobizes a metal itself and compounds containing the metal can be used.

The metal-based hydrophobizing liquid contains, for example, at least one of an amine having a hydrophobic group and an organosilicon compound.

The silicon-based hydrophobizing liquid is, for example, a silane coupling agent. The silane coupling agent may contain, for example, at least one of HMDS (hexamethyldisilazane), TMS (tetramethylsilane), fluorinated alkylchlorosilane, alkyldisilazane, and a non-chloro-based hydrophobizing agent.

The non-chloro-based hydrophobizing agent may contain, for example, at least one of dimethylsilyldimethylamine, dimethylsilyldiethylamine, hexamethyldisilazane, tetramethyldisilazane, bis(dimethylamino)dimethylsilane, N,N-dimethylaminotrimethylsilane, N-(trimethylsilyl)dimethylamine, and an organosilane compound.

The lower surface hydrophobizing liquid nozzle 15 is connected to a lower surface hydrophobizing liquid piping 47 that guides the hydrophobizing liquid to the lower surface hydrophobizing liquid nozzle 15. The lower surface hydrophobizing liquid piping 47 is provided with a lower surface hydrophobizing liquid valve 57 that opens/closes the lower surface hydrophobizing liquid piping 47.

The lower surface hydrophobizing liquid nozzle 15 is fixed in position with respect to the spin chuck 5 and is directed toward the peripheral edge region of the lower surface of the substrate W. When the lower surface hydrophobizing liquid valve 57 is opened, a continuous stream of the hydrophobizing liquid is discharged from the lower surface hydrophobizing liquid nozzle 15 toward the peripheral edge region of the lower surface. The lower surface hydrophobizing liquid nozzle 15 suffices to supply the hydrophobizing liquid to the lower surface of the substrate W and does not necessarily have to discharge the hydrophobizing liquid toward the peripheral edge region of the lower surface of the substrate W.

### <Third Example of Substrate Processing According to the Second Preferred Embodiment>

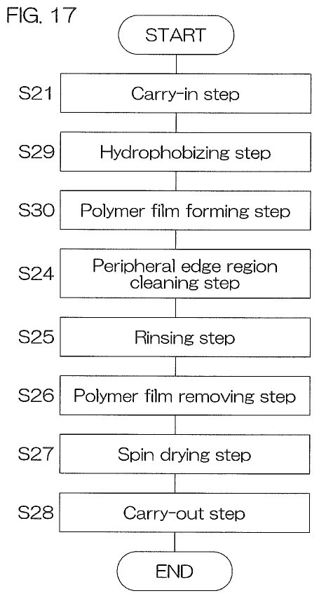

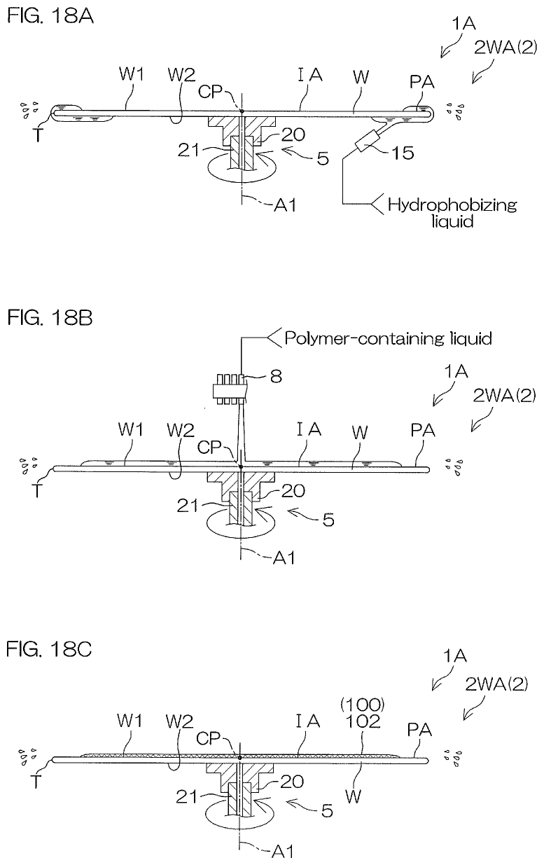

FIG. 17 is a flowchart for describing a third example of substrate processing executed by the substrate processing apparatus 1A. FIG. 18A to FIG. 18C are schematic views for describing conditions of the substrate W when the third example of substrate processing according to the second preferred embodiment is being performed.

Unlike in the first example of substrate processing according to the second preferred embodiment shown in FIG. 12, in the third example of substrate processing according to the second preferred embodiment, a hydrophobization step of hydrophobizing the peripheral edge region PA of the upper surface (first principal surface W1) of the substrate W is executed before the polymer film 100 is formed.

Specifically, as shown in FIG. 17, the carry-in step (step S21), a hydrophobization step (step S29), a polymer film forming step (step S30), the peripheral edge region cleaning step (step S24), the rinsing step (step S25), the polymer film removing step (step S26), the spin-drying step (step S27), and the carry-out step (step S28) are executed.

In the following, details of the third example of substrate processing according to the second preferred embodiment shall be described mainly with reference to FIG. 16 and FIG. 17. FIG. 18A to FIG. 18C shall be referenced where appropriate. Description of portions that are the same as the first example of substrate processing according to the second preferred embodiment shall be omitted.

The hydrophobization step (step S29) of selectively hydrophobizing the peripheral edge region PA of the upper surface of the substrate W is executed after the carry-in step (step S21).

Specifically, the lower surface hydrophobizing liquid valve 57 is opened. Thereby, the hydrophobizing liquid is discharged from the lower surface hydrophobizing liquid nozzle 15 toward the peripheral edge region of the lower surface of the substrate W as shown in FIG. 18A.

The hydrophobizing liquid that landed on the lower surface of the substrate W spreads toward the peripheral edge T of the substrate W due to the centrifugal force due to the rotation of the substrate W. At least a portion of the hydrophobizing liquid flows along the peripheral edge T of the substrate W and is supplied to the peripheral edge region PA (hydrophobizing liquid supplying step). The hydrophobizing liquid that flows along the peripheral edge T of the substrate W and is supplied to the peripheral edge region PA scatters from the peripheral edge T of the substrate W due to the centrifugal force. By the hydrophobizing liquid being supplied to the peripheral edge region PA, the peripheral edge region PA of the upper surface of the substrate W is hydrophobized.

After the peripheral edge region PA of the upper surface of the substrate W is selectively hydrophobized, the polymer film forming step (step S30) of forming the polymer film 100 on the upper surface of the substrate W is executed.

Specifically, the lower surface hydrophobizing liquid valve 57 is closed and the discharge of the hydrophobizing liquid from the lower surface hydrophobizing liquid nozzle 15 is stopped. After the discharge of the hydrophobizing liquid is stopped, the first nozzle driving mechanism 27 moves the polymer-containing liquid nozzle 8 to a processing position. The processing position of the polymer-containing liquid nozzle 8 is, for example, the central position. In the state where the polymer-containing liquid nozzle 8 is positioned at the processing position, the polymer-containing liquid valve 50 is opened. Thereby, the polymer-containing liquid is supplied (discharged) from the polymer-containing liquid nozzle 8 toward the center portion CP (inner side region IA) of the upper surface of the substrate W as shown in FIG. 18B (polymer-containing liquid supplying step, polymer-containing liquid discharging step).

The polymer-containing liquid discharged from the polymer-containing liquid nozzle 8 lands on the center portion CP of the upper surface of the substrate W. The polymer-containing liquid that landed on the upper surface of the substrate W spreads toward the peripheral edge T of the substrate W due to the centrifugal force due to the rotation of the substrate W. Here, since the peripheral edge region PA of the upper surface of the substrate W is hydrophobized, the polymer-containing liquid is removed from the peripheral edge region PA without remaining on the peripheral edge region PA. The inner side region IA can thus be covered with the polymer-containing liquid while exposing the peripheral edge region PA.

After the polymer-containing liquid has been supplied to the upper surface of the substrate W for a predetermined period, the polymer-containing liquid valve 50 is closed. The discharge of the polymer-containing liquid from the polymer-containing liquid nozzle 8 is thereby stopped. After the discharge of the polymer-containing liquid is stopped, the rotation of the substrate W is continued such that a portion of the polymer-containing liquid on the substrate W scatters outside the substrate W from the peripheral edge T of the substrate W. A liquid film of the polymer-containing liquid on the substrate W is thereby thinned (spin-off step, film thinning step). After the polymer-containing liquid valve 50 is closed, the polymer-containing liquid nozzle 8 is moved to the retreat position by the first nozzle driving mechanism 27.

The centrifugal force due to the rotation of the substrate W acts not just on the polymer-containing liquid on the substrate W but also on the gas in contact with the polymer-containing liquid on the substrate W. Therefore, by the action of the centrifugal force, a radial gas stream by which the gas is directed toward the peripheral edge T of the substrate W is formed. By the gas stream, the solvent in the gas state in contact with the polymer-containing liquid on the substrate W is eliminated from an atmosphere in contact with the substrate W. Evaporation (volatilization) of the solvent from the polymer-containing liquid on the substrate W is thus promoted and the polymer film 100 having the inner side covering portion 102 that covers the inner side region IA is formed as shown in FIG. 18C (evaporation forming step). Since remaining of the polymer-containing liquid on the peripheral edge region PA is suppressed by the hydrophobization, the forming of the polymer film 100 on the peripheral edge region PA is suppressed.

Unlike in the first example of substrate processing according to the second preferred embodiment, in the third example of substrate processing according to the second preferred embodiment, the polymer film 100 is practically not formed on the peripheral edge region PA and therefore, there is no need to execute the peripheral edge covering portion removing step. Further thereafter, the peripheral edge region cleaning step (step S24) to the carry-out step (step S28) are executed.

When the wet processing unit 2WA has the arrangement of the third example shown in FIG. 17, the following effect is exhibited in addition to the same effects as the substrate processing apparatus 1 according to the first preferred embodiment.

Specifically, the peripheral edge region PA can be hydrophobized selectively. The attachment of the polymer-containing liquid to the peripheral edge region PA can thus be suppressed. On the other hand, the inner side region IA is not hydrophobized and the polymer-containing liquid is thus likely to be retained on the inner side region IA. Therefore, if the polymer-containing liquid is supplied to the entirety of the first principal surface, the polymer film 100 that covers the inner side region IA in the state of exposing the peripheral edge region PA can be formed without devising a special means for supplying the polymer-containing liquid.

Unlike in the third example of the wet processing unit 2WA, an inclined hydrophobizing liquid nozzle 16 that faces the upper surface of the substrate W may be provided as indicated by alternate long and two short dashed lines in FIG. 16. In this case, the inclined hydrophobizing liquid nozzle 16 discharges the hydrophobizing liquid toward the peripheral edge region PA of the upper surface of the substrate W obliquely with respect to the upper surface of the substrate W in the hydrophobizing step (step S29). More specifically, the discharge direction is a direction of separating from the center portion CP (rotational axis A1) as the upper surface of the substrate W is approached.

Also, although with the third example of substrate processing according to the second preferred embodiment, it was stated that there is no need to execute the peripheral edge covering portion removing step, the removing liquid may be supplied to the peripheral edge region PA after the polymer film forming step (step S30) and before the peripheral edge region cleaning step (step S24). By doing so, even when the polymer becomes slightly attached to the peripheral edge region PA due to the supply of the polymer-containing liquid, the polymer can be removed from the peripheral edge region PA.

Also, after the third example of substrate processing according to the second preferred embodiment has been executed, a hydrophilization processing by which regions of the upper surface and lower surface of the substrate W that have been hydrophobized are hydrophilized again may be executed.

### Other Preferred Embodiments

The present invention is not restricted to the preferred embodiments described above and can be implemented in yet other modes.
(1) With the respective preferred embodiments described above with the exception of the third example of substrate processing according to the second preferred embodiment (see FIG. 17 to FIG. 18C), the inner side region IA can be covered by the polymer film 100 while exposing the peripheral edge region PA by covering the entirety of the upper surface of the substrate W with the polymer film 100 and thereafter removing the peripheral edge covering portion 101 of the polymer film 100. With the third example of substrate processing according to the second preferred embodiment, the inner side region IA can be covered by the polymer film 100 while exposing the peripheral edge region PA by selectively hydrophobizing the peripheral edge region PA.

That is, in all of the preferred embodiments, the polymer film forming step of forming the polymer film 100 such as to expose the peripheral edge region PA and cover the inner side region IA is executed. The method for forming the polymer film 100 is not restricted to the respective preferred embodiments described above. The polymer film 100 may be formed using a method differing from the respective preferred embodiments described above as long as the polymer film 100 can be formed such as to expose the peripheral edge region PA and cover the inner side region IA.
(2) By applying the wet processing unit 2WA according to the second preferred embodiment to the substrate processing apparatus 1 according to the first preferred embodiment, the substrate processing described with the second preferred embodiment can also be executed. That is, as long as the wet processing unit 2WA is provided, the respective substrate processing according to the second preferred embodiment can be executed regardless of whether or not the dry processing unit 2D is present.
(3) The processing orientation does not necessarily have to be the horizontal orientation. That is, unlike in FIG. 2, FIG. 11, FIG. 14, and FIG. 16, the processing orientation may be held in a vertical orientation or may be an orientation in which the principal surfaces of the substrate W are inclined with respect to a horizontal plane.

Also, the substrate W may be held such that the first principal surface W1 of the substrate W is the lower surface. That is, unlike in the substrate processing according to the respective preferred embodiments described above, processing may be performed on the lower surface of the substrate W. Specifically, a substrate processing apparatus may be arranged such that it is possible to execute a substrate processing where a polymer film is formed on the lower surface of the substrate W such that the peripheral edge region of the lower surface of the substrate W is exposed and an inner side region of the lower surface of the substrate W is covered and the peripheral edge region of the lower surface of the substrate W is cleaned by the first cleaning liquid.
(4) With the respective preferred embodiments described above, an arrangement is made such that a plurality of processing liquids are discharged from a plurality of nozzles. However, the mode of discharge of processing liquids is not restricted to the respective preferred embodiments described above. For example, unlike in the preferred embodiments described above, a processing liquid may be discharged from a fixed nozzle that is fixed in position inside the chamber 4 or an arrangement may be made such that all processing liquids are discharged toward the upper surface of the substrate W from a single nozzle. Also, if a liquid that differs from the rinse liquid is used as the second cleaning liquid, a nozzle (second cleaning liquid discharging member) that discharges the second cleaning liquid may be provided separately of the rinse liquid nozzle 10.

Also, each nozzle that supplies a processing liquid to the peripheral edge region PA of the upper surface of the substrate W may be provided in plurality along a circumferential direction of the spin base 20 (that is also a rotation direction of the substrate W).

The lower surface rinse liquid nozzle 12 may be provided in plurality along a circumferential direction of the spin base 20. By the rinse liquid being discharged toward the lower surface of the substrate W from a plurality of the lower surface rinse liquid nozzles 12, the rinse liquid can be supplied uniformly to the lower surface of the substrate W across an entire area in the circumferential direction. The same applies to the lower surface removing liquid nozzle 13 and the lower surface hydrophobizing liquid nozzle 15.

Further, although with the respective preferred embodiments described above, nozzles are given as examples of members that discharge processing liquids, the members that discharge the respective processing liquids are not restricted to nozzles. That is, the members that discharge the respective processing liquids suffice to be members that function as processing liquid discharging members upon discharging the processing liquids.
(5) With the respective preferred embodiments described above, the polymer film 100 is formed by supplying the polymer-containing liquid of a continuous stream to the upper surface of the substrate W and spreading the polymer-containing liquid by the centrifugal force. However, the method for supplying the polymer-containing liquid is not restricted to the method described above (see FIG. 6A, FIG. 6B, FIG. 13A, and FIG. 13B).

For example, the polymer-containing liquid nozzle 8 may be moved in a direction along the upper surface of the substrate W while supplying the polymer-containing liquid to the upper surface of the substrate W. Also, unlike in the respective preferred embodiments described above, in forming the polymer film 100, the polymer-containing liquid on the substrate W may be heated to promote evaporation of the solvent and promote the forming of the polymer film 100.

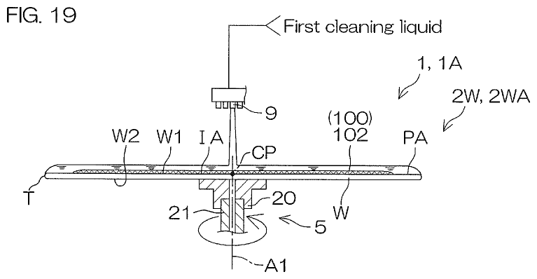

Also, unlike in the preferred embodiments described above, the polymer film 100 may be formed on the upper surface of the substrate W by coating the polymer-containing liquid on the upper surface of the substrate W. In detail, a coating member of bar shape with the polymer-containing liquid attached to a front surface may be moved along the upper surface of the substrate W while making it contact the upper surface of the substrate W to coat the polymer-containing liquid onto the upper surface of the substrate W.
(6) In the peripheral edge region cleaning step (step S9, S23) of the respective preferred embodiments described above, the first cleaning liquid is discharged toward the peripheral edge region PA of the upper surface of the substrate W. Unlike in the respective preferred embodiments described above, the first cleaning liquid may be discharged from the first cleaning liquid nozzle 9 toward the inner side region IA of the upper surface of the substrate W as shown in FIG. 19 in the peripheral edge region cleaning step (step S9, S23).

By doing so, the peripheral edge region PA can be cleaned while protecting, by the first cleaning liquid, the inner side covering portion 102 formed in the inner side region IA. Also, the first cleaning liquid discharged toward the inner side region IA lands on a front surface of the inner side covering portion 102 of the polymer film 100. The first cleaning liquid attached to the inner side covering portion 102 spreads radially on the inner side covering portion 102 and is expelled outside the substrate W through the peripheral edge region PA. Thus, in comparison to the case where the first cleaning liquid discharged from the first cleaning liquid nozzle 9 is made to land on the peripheral edge region PA, the first cleaning liquid can be made to spread across the peripheral edge region PA of a wide range and therefore, efficient cleaning can be realized.
(7) Unlike in the respective preferred embodiments described above, the rinsing step (step S10, S25) may be omitted. Also, in the rinsing step, the rinse liquid may be discharged toward the inner side region IA instead of discharging liquid toward the peripheral edge region PA. By doing so, the front surface of the inner side covering portion 102 of the polymer film 100 can be rinsed and the first cleaning liquid that splashed back from the peripheral edge region PA and became attached to the inner side covering portion 102 in the peripheral edge region cleaning step (step S9, S23) can be eliminated.

When the peripheral edge region cleaning step shown in FIG. 19 described above is adopted, the first cleaning liquid definitely becomes attached to the front surface of the inner side covering portion 102. It is therefore preferable to discharge the rinse liquid toward the inner side region IA in the rinsing step.
(8) Unlike in the first preferred embodiment described above, the wet processing unit 2W may be provided with the light emitting member 62. In this case, the light source of the light emitting member 62 is preferably disposed outside the chamber 4. For example, the light source may be disposed outside the chamber 4 and a tip of an optical fiber (not shown) that transmits the light L emitted from the light source may be disposed inside the chamber 4. If so, the photo-exposing step can be executed without providing the dry processing unit 2D.
(9) With the respective preferred embodiments described above, the spin chuck 5 is a suction type spin chuck that suctions the substrate W to the spin base 20. The spin chuck 5 is not restricted to a suction type spin chuck. For example, the spin chuck 5 may instead be a gripping type spin chuck that grips the peripheral edge of the substrate W by a plurality of gripping pins (not shown). If a gripping type spin chuck is adopted, it is preferable to switch holding of the substrate W between that by a first set of a plurality of gripping pins and that by a second set of a plurality of gripping pins when supplying processing liquids to the peripheral edge region PA of the upper surface of the substrate W.
(10) Although illustrations of pipings, pumps, valves, actuators, etc., have been partially omitted with the respective preferred embodiments described above, this does not mean that such members are not present and in actuality, these members are provided at appropriate positions.
(11) With the respective preferred embodiments described above, the controller 3 controls an entirety of the substrate processing apparatus 1. However, a controller that controls the respective members of the substrate processing apparatus 1 may be dispersed in a plurality of locations. Also, the controller 3 does not necessarily have to control the respective members directly and signals output from the controller 3 may be received by a secondary controller that controls the respective members of the substrate processing apparatus 1.
(12) Also, with the respective preferred embodiments described above, the substrate processing apparatus 1 or 1A includes the transfer robots (first transfer robot IR and second transfer robot CR), the plurality of processing units 2, and the controller 3. However, the substrate processing apparatus 1 or 1A may instead be arranged from a single processing unit 2 and the controller 3 and does not need to include a transfer robot. Or, the substrate processing apparatus 1 or 1A may be arranged from just a single processing unit 2. In other words, the processing unit 2 may be an example of a substrate processing apparatus.
(13) Also, although expressions such as “along,” “horizontal,” “vertical,” and “circular cylindrical” are used for the preferred embodiments described above, it is not required that “along,” “horizontal,” “vertical,” and “circular cylindrical” apply strictly. That is, the respective expressions allow deviations in manufacturing precision, installation precision, etc.
(14) Also, although respective arrangements are indicated by blocks in some cases, the shapes, sizes, and positional relationships of the respective blocks do not indicate the shapes, sizes, and positional relationships of the respective arrangements.

While preferred embodiments of the present invention have been described in detail above, these are merely specific examples used to clarify the technical contents of the present invention, and the present invention should not be interpreted as being limited only to these specific examples, and the scope of the present invention shall be limited only by the appended claims.

### REFERENCE SIGNS LIST

1: substrate processing apparatus
1A: substrate processing apparatus
9: first cleaning liquid nozzle (first cleaning liquid discharging member)
10: rinse liquid nozzle (second cleaning liquid discharging member)
13: lower surface removing liquid nozzle (removing liquid discharging member)
14: inclined removing liquid nozzle (removing liquid discharging member)
15: lower surface hydrophobizing liquid nozzle (hydrophobicing liquid discharging member)
100: polymer film
101: peripheral edge covering portion
102: inner side covering portion
IA: inner side region
PA: peripheral edge region
W: substrate
W1: first principal surface
W2: second principal surface

1. A substrate processing method for processing a substrate having a first principal surface and a second principal surface at an opposite side to the first principal surface, the substrate processing method comprising:
a polymer film forming step of forming a polymer film such as to expose a peripheral edge region of the first principal surface and cover an inner side region of the first principal surface positioned further to an inner side than the peripheral edge region and being adjacent to the peripheral edge region;
a first cleaning liquid supplying step of supplying, after the polymer film forming step, a first cleaning liquid to the first principal surface such that the polymer film is maintained on the first principal surface; and
a removing liquid supplying step of supplying, after the first cleaning liquid supplying step, a removing liquid that dissolves the polymer film more easily than the first cleaning liquid to the first principal surface.

2. The substrate processing method according to claim 1, wherein the polymer film forming step includes
a covering step of forming the polymer film having a peripheral edge covering portion that covers the peripheral edge region and an inner side covering portion that covers the inner side region, and
a peripheral edge exposing step of exposing the peripheral edge region by removing the peripheral edge covering portion from the first principal surface.

3. The substrate processing method according to claim 2, wherein the peripheral edge exposing step includes
a photo-exposing step of photo-exposing the peripheral edge covering portion, and
a second cleaning liquid discharging step of discharging, after the photo-exposing step, a second cleaning liquid, by which the photo-exposed peripheral edge covering portion is more easily dissolved than the inner side covering portion, from a second cleaning liquid discharging nozzle toward the first principal surface.

4. The substrate processing method according to claim 3, wherein the second cleaning liquid discharging step includes a step of discharging the second cleaning liquid toward the inner side region from the second cleaning liquid discharging nozzle.

5. The substrate processing method according to claim 2, wherein the peripheral edge exposing step includes a peripheral edge removing liquid supplying step of discharging the removing liquid toward the second principal surface from a removing liquid discharging nozzle that faces the second principal surface and supplying the removing liquid to the peripheral edge region by making it flow along a peripheral edge of the substrate.

6. The substrate processing method according to claim 2, wherein the peripheral edge exposing step includes an inclined removing liquid discharging step of discharging the removing liquid toward the peripheral edge region obliquely with respect to the first principal surface from a removing liquid discharging nozzle that faces the first principal surface.

7. The substrate processing method according to claim 1, wherein the first cleaning liquid supplying step includes a step of discharging the first cleaning liquid from a first cleaning liquid discharging nozzle toward the inner side region.

8. The substrate processing method according to claim 1, further comprising: a hydrophobizing step of hydrophobizing the peripheral edge region before the polymer film forming step; and
wherein the polymer film forming step includes a polymer-containing liquid supplying step of supplying a polymer-containing liquid containing a polymer and a solvent to the first principal surface, and an evaporation forming step of evaporating the solvent from the polymer-containing liquid on the first principal surface and forming the polymer film.

9. The substrate processing method according to claim 8, wherein the hydrophobizing step includes a hydrophobizing liquid supplying step of discharging a hydrophobizing liquid toward the second principal surface from a hydrophobizing liquid discharging nozzle and making the hydrophobizing liquid reach the peripheral edge region by making the hydrophobizing liquid flow along the peripheral edge of the substrate.
